(19) United States
(12) Patent Application Publication
(10) Pub. No.: US 2014/0117359 A1
(43) Pub. Date: May 1, 2014

(54) ARRAY SUBSTRATE AND METHOD FOR MANUFACTURING THE SAME AND DISPLAY DEVICE

(71) Applicant: BOE TECHNOLOGY GROUP CO., LTD., Beijing (CN)

(72) Inventors: Guangcai YUAN, Beijing (CN); Woobong LEE, Beijing (CN)

(73) Assignee: BOE TECHNOLOGY GROUP CO., LTD., Beijing (CN)

(21) Appl. No.: 13/755,100

(22) Filed: Jan. 31, 2013

(30) Foreign Application Priority Data
Oct. 26, 2012 (CN) 201210418592.X
Nov. 30, 2012 (CN) 201210506159.1

(51) Int. Cl. H01L 29/786

(52) U.S. Cl. CPC H01L 29/7869
USPC 257/59

(57) ABSTRACT

The present invention relate to a display device, an array substrate and a method for manufacturing the same. The array substrate includes a substrate and a thin film transistor and a pixel electrode which are formed on the substrate, the thin film transistor includes a gate electrode, a gate insulating layer, an active layer, and source and drain electrodes and is overlaid with a passivation layer, the active layer of the thin film transistor is of an oxide semiconductor, and the passivation layer comprises at least one layer of inorganic insulating thin film or organic insulating thin film. With this array substrate, the oxide semiconductor can be effectively avoided from being affected by hydrogen-containing groups, so that stability of the whole TFT device is enhanced to a great extent, and yield of final products is increased.

### TECHNICAL FIELD

Embodiments of the present invention relate to an array substrate and a method for manufacturing the same and a display device.

### BACKGROUND

Oxide thin film transistors (TFTs) are such kind of thin film transistors that employ metal oxide semiconductors for active layers, and have such advantages as ultrathin profile, low power consumption, etc. They can not only be useful in manufacture of a liquid crystal display panel, but also can be used for a new generation of organic light-emitting diode (OLED) display panels.

Referring to FIG. 1 and FIGS. 2A to 2M, a method for manufacturing an oxide TFT array substrate in prior art will be described below.

FIG. 1 is a flow chart illustrating the method for manufacturing the oxide TFT array substrate in prior art, and FIGS. 2A to 2M are cross-sectional views in the course of manufacturing the oxide TFT array substrate.

S101′, a gate metal thin film is formed on a substrate.

As shown in FIG. 2A, a gate metal thin film 13 is formed on a substrate 12. During manufacture of TFTs, gate metal thin films are mostly manufactured by means of magnetron sputtering, and materials for them can be selected according to different device structures and process requirements. The substrate 12 may be a glass substrate, a quartz substrate or other transparent substrate of an inorganic material, or may also be a transparent substrate produced by using an organic flexible material.

S102′, the gate metal thin film is patterned so as to form a gate line and a gate electrode.

As shown in FIG. 2B, by means of wet etching, the gate metal thin film 13 is patterned so as to obtain a gate line (not shown in the figure), a gate electrode 13a, and a common electrode line 13b. The common electrode line may not be produced depending on a specific design.

S103′, a gate insulating layer is formed on the gate electrode.

As shown in FIG. 2C, after patterning of the gate electrode, through a pre-clean process (cleaning before film formation), a plasma enhanced chemical vapor deposition (PECVD) and so on, a gate insulating layer 14 is produced on the substrate formed with the gate pattern.

S104′, an oxide semiconductor thin film is formed.

As shown in FIG. 2D, an oxide semiconductor thin film 15 is formed. A very key stage for manufacture of oxide TFTs is manufacture of an oxide semiconductor thin film. The widely used oxide semiconductors at present include indium gallium zinc oxide (IGZO), indium gallium tin oxide (IGTO), indium zinc oxide (ILO) and so on, and compositions related to these materials in other different stoichiometries. The main manufacturing methods comprise a magnetron sputtering deposition, a solution method, etc.

S105′, the oxide semiconductor thin film is patterned so as to form an active layer for an oxide TFT.

As shown in FIG. 2E, the oxide semiconductor thin film is patterned so as to attain the pattern of an active layer 15a. For the patterning process of an active-layer oxide semiconductor, there are two main etching processes, i.e., one is a wet etching process, and the other is a dry etching process. However, use of different methods will cause different damages to the oxide semiconductor layer.

S106′, a thin film for an etch stop layer is formed and patterned.

As shown in FIG. 2F, a thin film 16 for an etch stop layer (ESL) is formed for reducing the damages to the active layer formed from oxide semiconductor in the course of the subsequent patterning of a data line. After formation of the thin film for the etch stop layer, a patterning is carried out so as to form an etch stop layer 16a, as shown in FIG. 2G.

S107′, a source-drain metal layer is formed and patterned to form a source electrode, a drain electrode and a data line.

As shown in FIG. 2H, during manufacturing process of a LCD, firstly, a source-drain metal layer 17 is deposited, and then is patterned by means of wet etching, and next a source electrode 17b, a drain electrode 17a (as shown in FIG. 2I) and a data line (not shown in the figure) integrally formed with the source electrode 17b are formed.

During manufacturing process of an OLED, a source electrode, a drain electrode and a power supply line integrally formed with or connected to the source electrode are formed after a source-drain metal layer is patterned in this step.

S108′, a passivation layer is formed and a via-hole etching is performed therein.

As shown in FIG. 2J, after patterning of the data line or the power supply line, a passivation layer 18 is formed on the whole substrate plane. After formation of the passivation layer, a via-hole etching is carried out to form a via hole 19b for realizing connection of the drain electrode 17a to a pixel electrode, as shown in FIG. 2K. Furthermore, during the etching, a via hole may also be formed over the source electrode 17b so as to connect the source electrode 17b with a signal access terminal, such as the data line or power supply line produced on a different layer as the source electrode 17b.

S109′, a pixel electrode layer is deposited and patterned.

As shown in FIG. 2L, after formation of the via holes, a pixel electrode layer 20, for which indium tin oxide (ITO) material is now widely adopted, is formed, and is patterned by means of wet etching so as to form a pixel electrode 20a and a contact electrode 20b, as shown in FIG. 2M.

During the above-mentioned manufacturing process of the array substrate, hydrogen-containing groups, such as OH— and H+, are not possibly avoided from being doped in the passivation layer or hydrogen elements are absorbed in the manufacturing process of the passivation layer. These hydrogen-containing groups are easily broken during manufacture of the device and in the state that the device operates, and are probably diffused into the oxide semiconductor layer as the time goes by and the environment changes. The diffused substances such as OH—, H₂O, H+ and the like will disadvantageously affect stability of the device, so that a relatively large drift happens to the threshold voltage Vth of an oxide thin film transistor device, and even malfunction of the product may occur.

### SUMMARY

According to embodiments of the present invention, an array substrate and a method for manufacturing the same, and a display device, are provided for overcoming problems in an existing array substrate that doped hydrogen groups tend to destroy stability of the device and adversely affect yield of products.

In one aspect of the invention, there is provided an array substrate, comprising a substrate and a thin film transistor and a pixel electrode which are formed on the substrate, the thin film transistor comprising a gate electrode, a gate insulating layer, an active layer and source and drain electrodes, and being overlaid with a passivation layer; wherein the active layer of the thin film transistor is of an oxide semiconductor; and the passivation layer comprises at least one layer of inorganic insulating thin film or organic insulating thin film.

As for the array substrate, for example, the passivation layer is in a single layer, comprising a first passivation layer, which may be an inorganic insulating layer or an organic insulating layer; the inorganic insulating layer comprises a silicon oxide thin film, a silicon nitride thin film, a silicon oxynitride thin film, an aluminum oxide thin film, a titanium oxide thin film, a zirconium oxide thin film, a tantalum oxide thin film, a barium titanate thin film, or a neodymium oxide thin film; and the organic insulating layer comprising a resin insulating film or an acrylic insulating film.

For example, when the first passivation layer is an inorganic insulating layer, a thickness is 50 nm˜500 nm; when the first passivation layer is an organic insulating layer, a thickness is 0.5 μm˜2.5 μm.

For example, the first passivation layer is a passivation layer subjected to an annealing process.

As for the array substrate, for example, the passivation layer is in a double-layered structure, comprising a first passivation layer close to the source-drain electrode layer and a second passivation layer; the first passivation layer is a first inorganic insulating layer, which may comprise a silicon oxide thin film, an aluminum oxide thin film, an yttrium oxide thin film, a zirconium oxide thin film, a tantalum oxide thin film, a barium titanate thin film, a neodymium oxide thin film or a silicon oxynitride thin film; the second passivation layer is a second inorganic insulating layer or a first organic insulating layer; the second inorganic insulating layer may comprise a silicon nitride thin film, an yttrium oxide thin film, a silicon oxynitride thin film, a zirconium oxide thin film, a tantalum oxide thin film, a barium titanate thin film or a neodymium oxide thin film; and the first organic insulating layer may comprise a resin insulating film or an acrylic insulating film.

For example, a thickness of the first passivation layer may be 50 nm˜600 nm.

For example, when the second passivation layer is an inorganic insulating layer, the thickness of the second passivation layer may be 50 nm˜500 nm.

For example, when the second passivation layer is an organic insulating layer, the thickness of the second passivation layer may be 0.5 μm˜2.5 μm.

For example, each of the first passivation layer and the second passivation layer is a passivation layer subjected to an annealing process.

As for the array substrate, for example, the passivation layer has a three-layered structure, which includes a first passivation layer, a second passivation layer, and a third passivation layer which are disposed in sequence; wherein the first passivation layer is close to the thin film transistor; the first passivation layer is a first inorganic insulating layer, which comprises a silicon oxide thin film, an aluminum oxide thin film, a titanium oxide thin film, a silicon oxynitride thin film, a zirconium oxide thin film, a tantalum oxide thin film, a barium titanate thin film or a neodymium oxide thin film; the second passivation layer is a second inorganic insulating layer or a first organic insulating layer; the second inorganic insulating layer comprises a silicon oxynitride thin film, an aluminum oxynitride thin film, a zirconium oxynitride thin film, a tantalum oxynitride thin film, or a neodymium oxynitride thin film; and the first organic insulating layer comprises a resin insulating thin film or an acrylic insulating thin film; and the third passivation layer is a third inorganic insulating layer or a second organic insulating layer; the third inorganic insulating layer comprises a silicon nitride thin film, an aluminum nitride thin film, a zirconium nitride thin film, or a tantalum nitride thin film; and the second organic insulating layer comprises a resin insulating thin film or an acrylic insulating thin film.

For example, a thickness of the first passivation layer is 50 nm˜600 nm; when the second passivation layer is an inorganic insulating layer, a thickness of the second passivation layer is 50 nm˜650 nm; and when the second passivation layer is an organic insulating layer, a thickness of the second passivation layer is 0.5 μm˜2.5 μm; when the third passivation layer is an inorganic insulating layer, a thickness of the third passivation layer is 50 nm˜500 nm; and when the third passivation layer is an organic insulating layer, a thickness of the third passivation layer is 0.5 μm˜2.5 μm.

As for the array substrate, for example, the passivation layer is in a four-layered structure, comprising a first passivation layer, a second passivation layer, a third passivation layer, and a fourth passivation layer which are provided in sequence; the first passivation layer is close to the thin film transistor, and is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, or a neodymium oxynitride thin film; the second passivation layer is a second inorganic insulating layer, which may comprise an aluminum oxynitride thin film, a zirconium oxynitride thin film, a tantalum oxynitride thin film or a neodymium oxynitride thin film; the third passivation layer is a third inorganic insulating layer, which may comprise a silicon nitride thin film, an aluminum nitride thin film, a zirconium nitride thin film or a tantalum nitride thin film; the fourth passivation layer is a first organic insulating layer, which may comprise a resin insulating thin film or an acrylic insulating thin film.

For example, a thickness of the first passivation layer may be 50 nm˜600 nm; a thickness of the second passivation layer may be 50 nm˜650 nm; a thickness of the third passivation layer may be 50 nm˜500 nm; and a thickness of the fourth passivation layer may be 0.5 μm˜2.5 μm.

As for the array substrate, for example, the passivation layer is in a five-layered structure, comprising a first passivation layer, a second passivation layer, a third passivation layer, a fourth passivation layer, and a fifth passivation layer which are provided in sequence; the first passivation layer is close to the source-drain electrode layer; the first passivation layer is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, or a neodymium oxynitride thin film; the second passivation layer is a second inorganic insulating layer, which may comprise an aluminum oxynitride thin film, a zirconium oxynitride thin film, a tantalum oxynitride thin film or a neodymium oxynitride thin film; the third passivation layer is a third inorganic insulating layer, which may comprise a silicon nitride thin film, an aluminum nitride thin film, a zirconium nitride thin film or a tantalum nitride thin film; the fourth passivation layer is a first organic insulating layer, which may comprise a resin insulating thin film or an acrylic insulating thin film; the fifth passivation layer is a fourth inorganic insulating layer, which may comprise a silicon oxynitride thin film, a silicon oxide thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, a neodymium oxynitride thin film, a silicon nitride thin film, an aluminum nitride thin film, a zirconium nitride thin film or a tantalum nitride thin film.

For example, a thickness of the first passivation layer may be 50 nm˜600 nm; a thickness of the second passivation layer may be 50 nm˜650 nm; a thickness of the third passivation layer may be 50 nm˜500 nm; a thickness of the fourth passivation layer may be 0.5 μm˜2.5 μm; and a thickness of the fifth passivation layer can be 20 nm˜450 nm.

As for the array substrate, for example, the gate insulating layer is located between the active layer and the gate electrode; and the gate insulating layer comprises at least one layer of inorganic insulating thin film.

For example, the gate insulating layer has a one-layered structure, and comprises a first gate insulating layer, which may be a silicon oxide thin film, a yttrium oxide thin film, an aluminum oxide thin film, a titanium oxide thin film, a zirconium oxide thin film, a tantalum oxide thin film, a barium titanate thin film, a neodymium oxide thin film, an aluminum oxynitride thin film, a silicon oxynitride thin film, a zirconium oxynitride thin film, a tantalum oxynitride thin film, an yttrium oxynitride thin film, a neodymium oxynitride thin film, a silicon nitride thin film, an aluminum nitride thin film, a zirconium nitride thin film, or a tantalum nitride thin film.

For example, the first gate insulating layer is an insulating layer subjected to an annealing process.

For example, a thickness of the first gate insulating layer may be 50 nm˜500 nm.

For example, the gate insulating layer includes a first gate insulating layer close to the gate electrode and a second gate insulating layer close to the active layer; the first gate insulating layer is an aluminum oxynitride thin film, a silicon oxynitride thin film, a zirconium oxynitride thin film, a tantalum oxynitride thin film, an yttrium oxynitride thin film, a neodymium oxynitride thin film, a silicon nitride thin film, an aluminum nitride thin film, a zirconium nitride thin film or a tantalum nitride thin film; and the second gate insulating layer is a silicon oxide thin film, an yttrium oxide thin film, an aluminum oxide thin film, a titanium oxide thin film, a zirconium oxide thin film, a tantalum oxide thin film, a barium titanate thin film, a neodymium oxide thin film, an aluminum oxynitride thin film, a silicon oxynitride thin film, a zirconium oxynitride thin film, a tantalum oxynitride thin film, an yttrium oxynitride thin film or a neodymium oxynitride thin film.

For example, the first gate insulating layer is an insulating layer subjected to an annealing process; and the second gate insulating layer is an insulating layer subjected to an annealing process.

For example, a thickness of the first gate insulating layer may be 50 nm˜600 nm; and a thickness of the second gate insulating layer may be 50 nm˜650 nm.

For example, the gate insulating layer includes a three-layered structure, which comprises a first gate insulating layer close to the gate electrode, a second gate insulating layer, and a third gate insulating layer close to the active layer, and the second gate insulating layer is located between the first gate insulating layer and the third gate insulating layer; wherein the first gate insulating layer is an aluminum oxynitride thin film, a silicon oxynitride thin film, a zirconium oxynitride thin film, a tantalum oxynitride thin film, an yttrium oxynitride thin film, a neodymium oxynitride thin film, a silicon nitride thin film, an aluminum nitride thin film, a zirconium nitride thin film or a tantalum nitride thin film; the second gate insulating layer is an aluminum oxynitride thin film, a silicon oxynitride thin film, a zirconium oxynitride thin film, a tantalum oxynitride thin film, an yttrium oxynitride thin film, or a neodymium oxynitride thin film; and the third gate insulating layer is a silicon oxide thin film, an yttrium oxide thin film, an aluminum oxide thin film, a titanium oxide thin film, a zirconium oxide thin film, a tantalum oxide thin film, a barium titanate thin film, a neodymium oxide thin film, an aluminum oxynitride thin film, a silicon oxynitride thin film, a zirconium oxynitride thin film, a tantalum oxynitride thin film, an yttrium oxynitride thin film or a neodymium oxynitride thin film.

For example, a thickness of the first gate insulating layer may be 50 nm˜600 nm; a thickness of the second gate insulating layer may be 50 nm˜650 nm; and a thickness of the third gate insulating layer can be 20 nm˜600 nm.

For example, the gate electrode and/or the source and drain electrodes are electrodes of copper or copper alloy.

In another aspect of the invention, there is provided a method for manufacturing the array substrate, comprising a step of producing a passivation layer, the passivation layer including at least one layer of inorganic insulating thin film or organic insulating thin film.

As for the method for manufacturing the array substrate, for example, the passivation is in a single layer and comprises a first passivation layer, the passivation layer may be manufactured by:

Step S11, forming the first passivation layer with an inorganic insulating material and an organic insulating material; and

Step S12, performing an annealing process on the first passivation layer.

For example, the annealing process may be: a heating chamber with nitrogen gas or air is incorporated into a PECVD apparatus, and a dehydrogenizing process is performed on the first passivation layer; the temperature in the annealing chamber may be 200° C.˜350° C., and the annealing time period may be 15 min˜90 min.

As for the method for manufacturing the array substrate, for example, the passivation is in a double-layered structure, comprising a first passivation layer close to the source-drain electrode layer and a second passivation layer, the passivation layer may be manufactured by:

Step S21, forming the first passivation layer with an inorganic insulating material;

Step S22, performing an annealing process on the first passivation layer;

Step S23, forming the second passivation layer with an inorganic insulating material and an organic insulating material; and

Step S24, performing an annealing process on the second passivation layer.

For example, the annealing process may be: a heating chamber with nitrogen gas or air is incorporated into a PECVD apparatus, and a dehydrogenizing process is performed on the first passivation layer; the temperature in the annealing chamber may be 200° C.˜350° C., and the annealing time period may be 15 min˜90 min.

As for the method for manufacturing the array substrate, for example, the passivation is in a three-layered structure, which includes a first passivation layer, a second passivation layer, and a third passivation layer which are disposed in sequence, the first passivation layer is close to the thin film transistor, and the passivation layer may be manufactured by:

Step S31, forming the first passivation layer with an inorganic insulating material;

Step S32, forming the second passivation layer with an inorganic insulating material and an organic insulating material; and

Step S33, forming the third passivation layer with an inorganic insulating material and an organic insulating material.

As for the method for manufacturing the array substrate, for example, the passivation is in a four-layered structure, comprising a first passivation layer, a second passivation layer, a third passivation layer, and a fourth passivation layer which are provided in sequence; the first passivation layer is close to the thin film transistor, and the passivation layer may be manufactured by:

Step S41, forming the first passivation layer with an inorganic insulating material;

Step S42, forming the second passivation layer with an inorganic insulating material;

Step S43, forming the third passivation layer with an inorganic insulating material; and

Step S44, forming the fourth passivation layer with an organic insulating material.

As for the method for manufacturing the array substrate, for example, the passivation is in a five-layered structure, comprising a first passivation layer, a second passivation layer, a third passivation layer, a fourth passivation layer, and a fifth passivation layer which are provided in sequence; the first passivation layer is close to the source-drain electrode layer, and the passivation layer may be manufactured by:

Step S41, forming the first passivation layer with an inorganic insulating material;

Step S42, forming the second passivation layer with an inorganic insulating material;

Step S43, forming the third passivation layer with an inorganic insulating material;

Step S44, forming the fourth passivation layer with an organic insulating material; and

Step S55, forming the fifth passivation layer with an inorganic insulating material.

In still another aspect of the invention, there is provided a display device, comprising the above array substrate.

According to the array substrate and method for manufacturing the same and the display device provided in embodiments of the invention, the gate insulating layer and the passivation layer in the array substrate are produced by using a layered structure in combination with an annealing process. Hydrogen-containing groups in the passivation layer and in the outside environment can be decreased to a great extent by using the layered structure, so that the oxide semiconductor can be effectively avoided from being affected by the hydrogen-containing group. Thus, stability of the whole TFT device is enhanced to a great extent and yield of final products is increased.

### BRIEF DESCRIPTION OF THE DRAWINGS

In order to illustrate the technical solutions of the embodiments of the invention more clearly, the drawings of the embodiments will be briefly described in the following; it is obvious that the drawings described below are only related to some embodiments of the invention and thus are not limitative of the invention.

FIG. 1 is a flow chart showing a method for manufacturing an oxide thin film transistor array substrate in prior art;

FIGS. 2A to 2M are the first to thirteenth schematic views showing the manufacture of the oxide thin film transistor array substrate in prior art, respectively;

FIG. 3 is a structurally schematic view showing an array substrate according to a first embodiment of the invention;

FIG. 4 is a flow chart showing a method for manufacturing the array substrate according to the first embodiment of the invention;

FIG. 5 is a structurally schematic view showing an array substrate according to a third embodiment of the invention;

FIG. 6 is an another schematic view showing the structure of the array substrate according to the third embodiment of the invention;

FIG. 7 is a flow chart showing a method for manufacturing the array substrate according to the third embodiment of the invention;

FIG. 8 is a structurally schematic view showing an array substrate according to a fifth embodiment of the invention;

FIG. 9 is a flow chart showing a method for manufacturing the array substrate according to the fifth embodiment of the invention;

FIG. 10 is a structurally schematic view showing an array substrate according to a seventh embodiment of the invention;

FIG. 11 is a flow chart showing a method for manufacturing the array substrate according to the seventh embodiment of the invention;

FIG. 12 is a structurally schematic view showing an array substrate according to a ninth embodiment of the invention; and

FIG. 13 is a flow chart showing a method for manufacturing the array substrate according to the ninth embodiment of the invention.

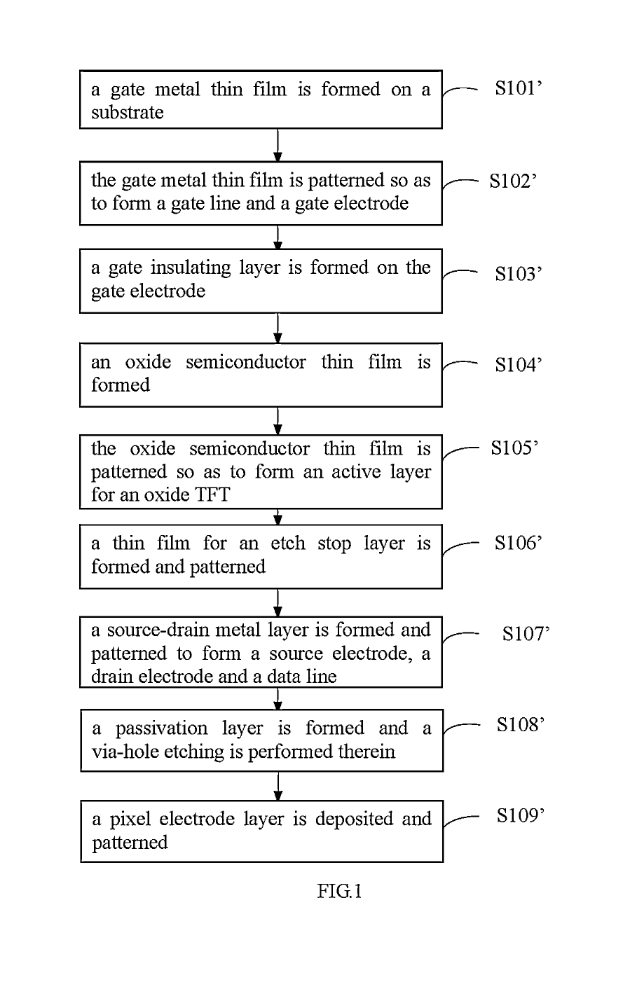

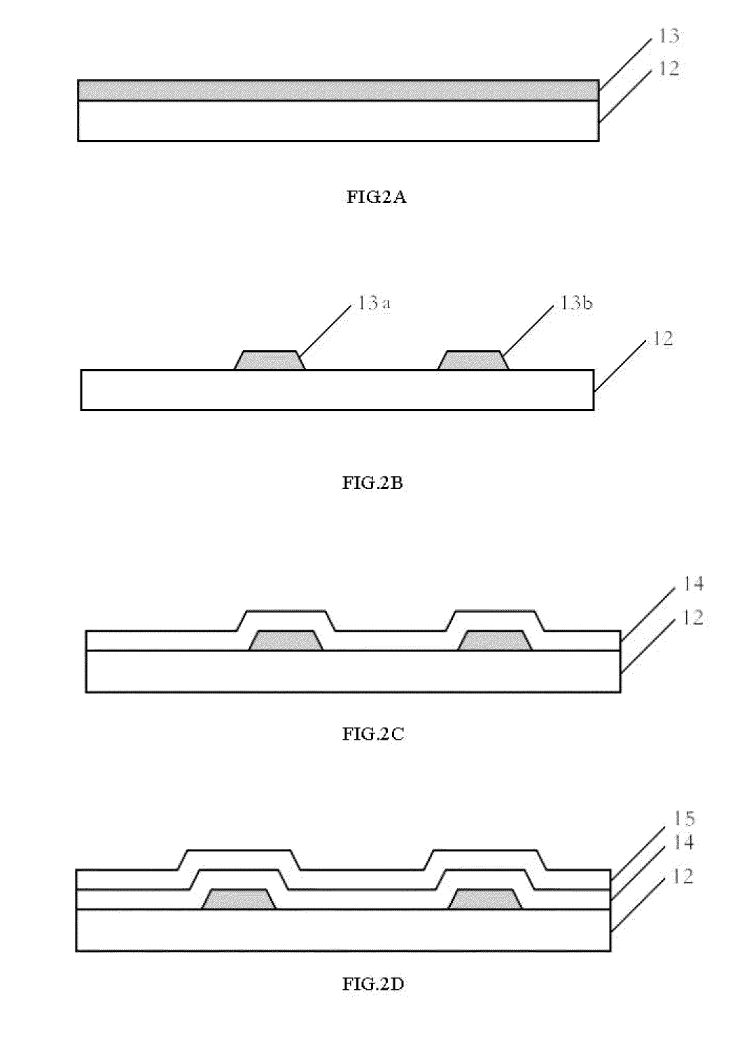

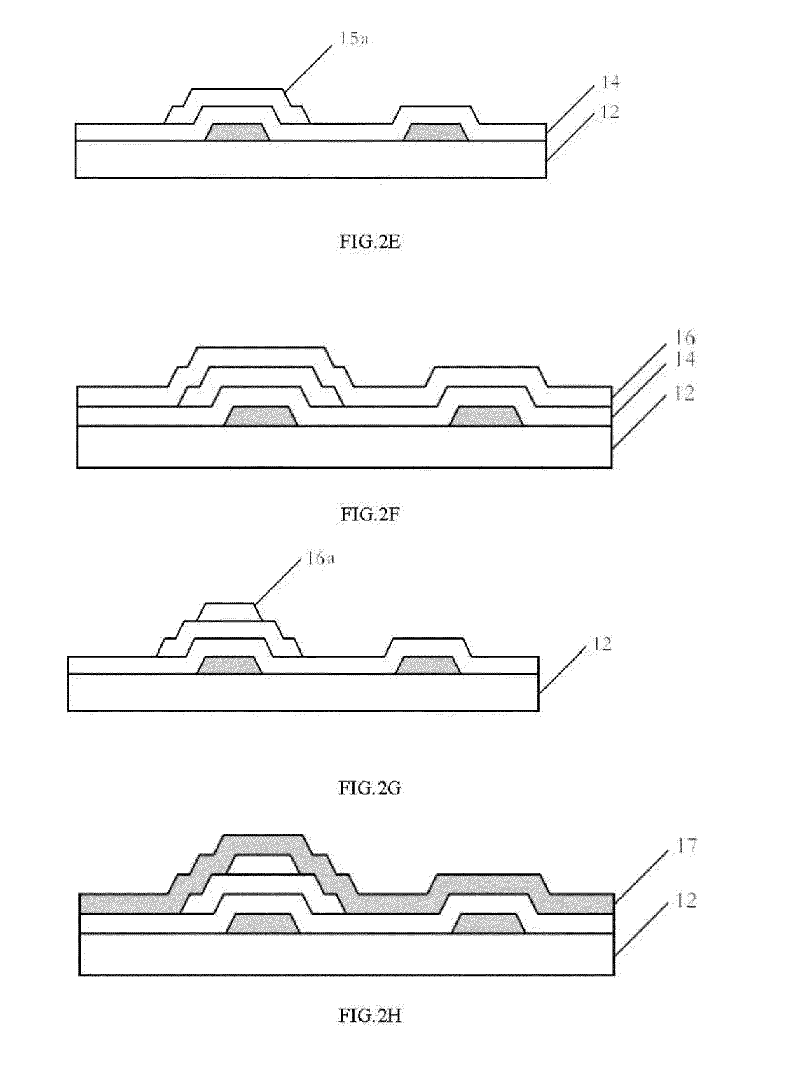

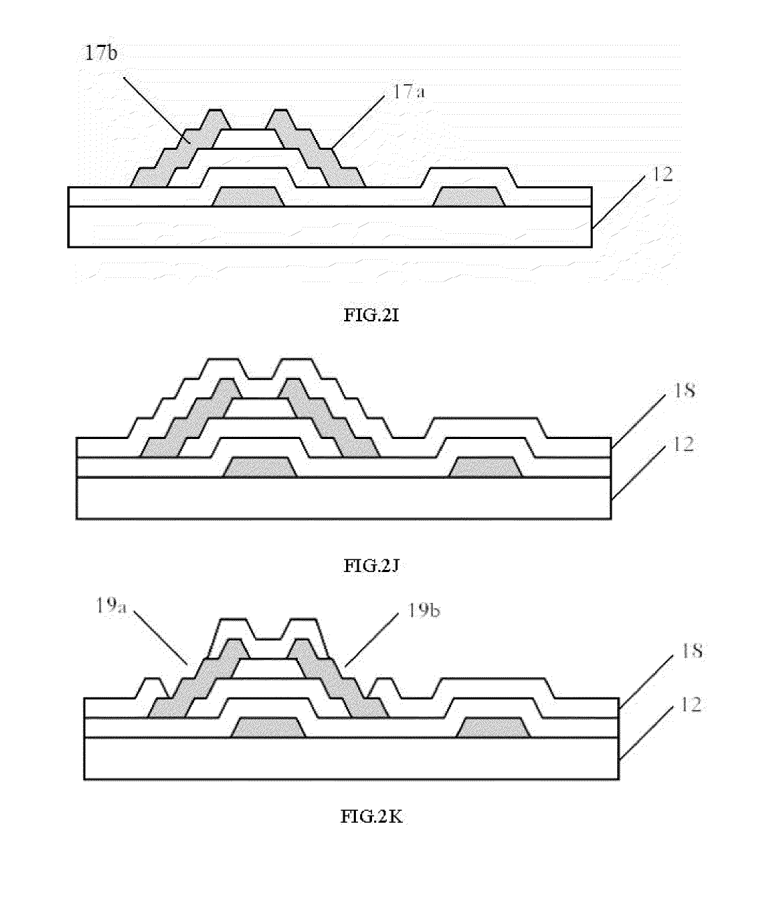

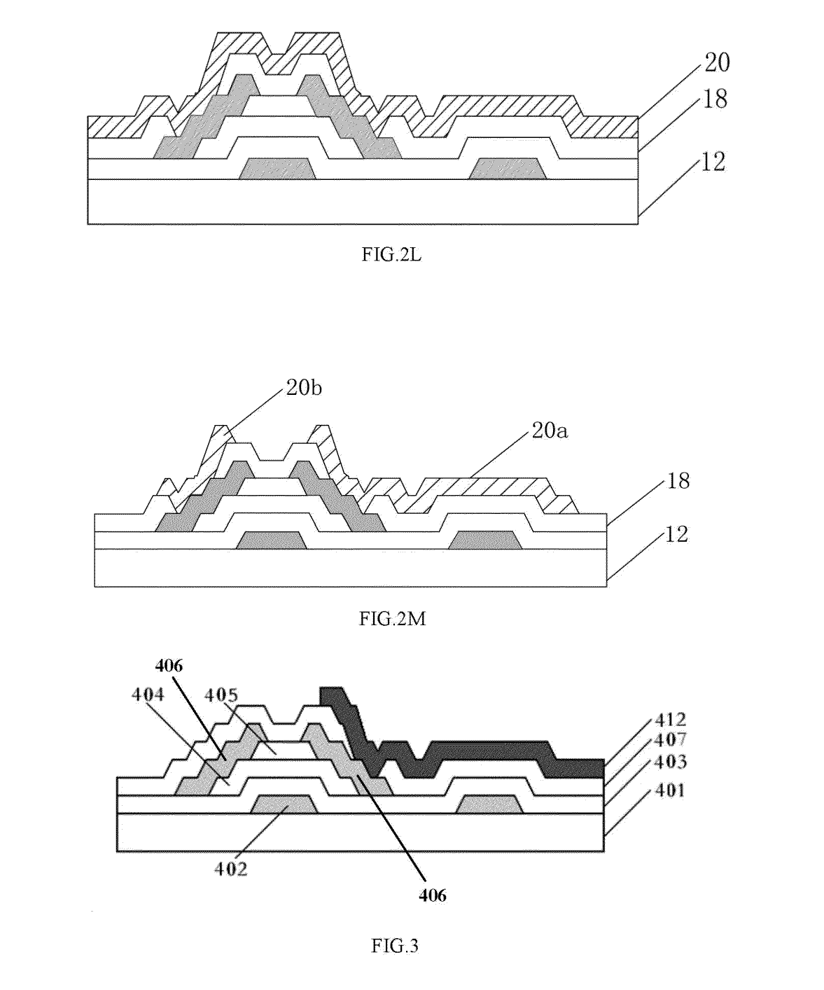

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein should have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” “the,” etc., are not intended to limit the amount, but indicate the existence of at lease one. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

In the following described embodiments and the corresponding accompanying drawings, array substrates of twisted nematic (TN) mode LCD are described as examples to introduce an improved technical solution provided by the invention, but the present invention is not limited thereto.

An array substrate according to embodiments of the invention, for example, comprises a plurality of gate lines and a plurality of data lines, and these gate lines and data lines intersect each other to thereby define pixel units arranged in an array; each of the pixel units may include a thin film transistor functioning as a switch element and a pixel electrode. For example, for the thin film transistor of each of the pixel units, its gate electrode is electrically connected to or integrally formed with a corresponding gate line, its source electrode is electrically connected to or integrally formed with a corresponding data line, and its drain electrode is electrically connected to or integrally formed with the corresponding pixel electrode. The following descriptions are mainly made on a single pixel unit or a plurality of pixel units, but other pixel units may be formed in the same way.

### Embodiment 1

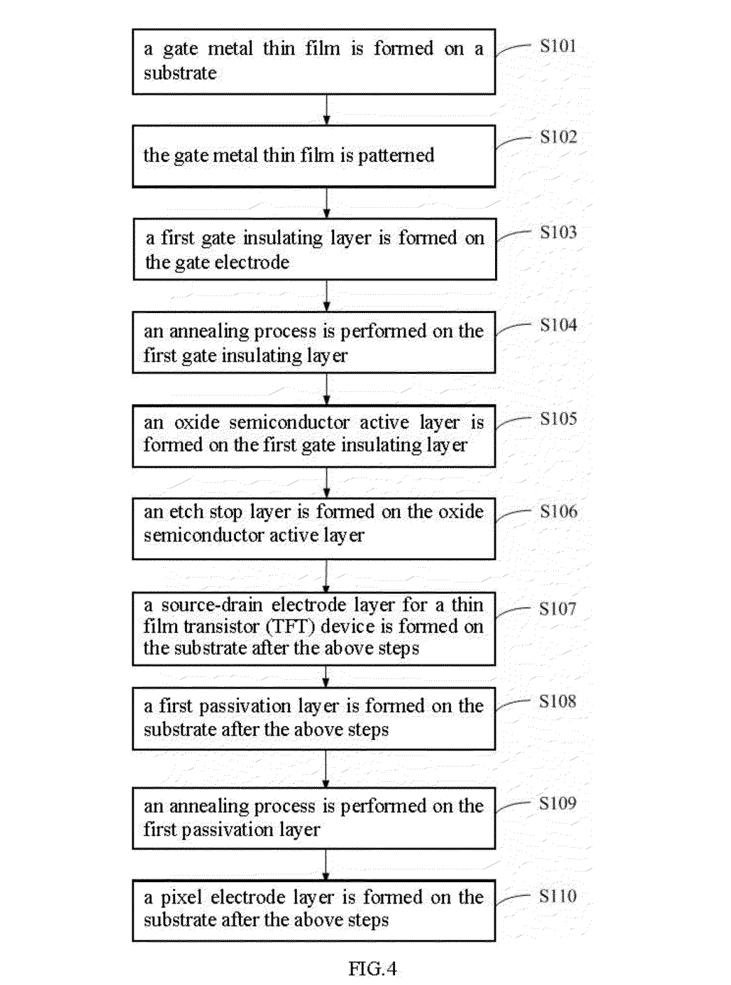

As shown in FIG. 3, an array substrate provided in the present embodiment has such an array substrate structure in which the gate layer for a thin film transistor is located at the bottom (i.e., a bottom-gate type). The array substrate comprises: a gate electrode 402 located on a substrate 401, a gate insulating layer 403 and an active layer 404 which are located over the gate electrode 402 respectively, a source-drain electrode layer 406, a pixel electrode layer 412 and a passivation layer. The gate insulating layer 403 is located between the gate electrode 402 and the active layer 404; and the passivation layer is located between the source-drain electrode layer 406 and the pixel electrode layer 412. The source-drain electrode layer 406 includes a source electrode, a drain electrode and a data line (or a power supply line) which have been patterned. As the passivation layer is located between the source-drain electrode layer 406 and the pixel electrode layer 412, hydrogen element and complex of hydrogen in the passivation layer and hydrogen element and complex of hydrogen present in the outside environment are easily permeated into the oxide semiconductor active layer through a channel structure between the source electrode and the drain electrode. This may bring about some negative effects on properties of the oxide semiconductor, and in turn, performance of the whole device is affected. Therefore, in the embodiment, structure, substance and manufacturing process of the passivation layer is optimized, so that the effects on the whole device caused by hydrogen element and complex of hydrogen in the passivation layer and hydrogen element and complex of hydrogen from the outside environment are reduced to a great extent and then stability of safety of the whole device are enhanced.

The active layer 404 is of an oxide semiconductor, the gate electrode and/or the source and drain electrodes are made of Cu, Cu alloy, or any one of aluminum, chromium, molybdenum, titanium, neodymium and manganese, as well as any alloy of the above metals, and a stacked structure of the above metals. The source and drain electrodes include a source electrode and a drain electrode of the thin film transistor.

In the present embodiment, the passivation layer is in a single layer structure comprising a first passivation layer 407. The first passivation layer 407 may be an inorganic insulating layer comprising a silicon oxide thin film, a silicon nitride thin film, a silicon oxynitride thin film, an aluminum oxide thin film, a titanium oxide thin film, a zirconium oxide thin film, a tantalum oxide thin film, a barium titanate thin film, a neodymium oxide thin film or other thin film layer of an inorganic insulating material. A thickness of the first passivation layer 407 made from an inorganic insulating material may be 50 nm˜500 nm.

When the thickness of the first passivation layer 407 is in the range of 50 nm˜500 nm, it can assured that manufacture of the first passivation layer is completed in a shorter time, that is, the production efficiency is guaranteed, while the oxide semiconductor is effectively avoided from being affected by hydrogen-containing groups. If the thickness of the first passivation layer 407 is too thin, it cannot function to avoid the oxide semiconductor from being affected by hydrogen-containing groups; and if the thickness of the first passivation layer is too thick, a longer tact time is needed, causing reduction of the production efficiency.

In addition, the first passivation layer 407 may also be an organic insulating layer comprising a resin insulating film, an acrylic insulating film or other film layer using an organic insulating material. A thickness of the first passivation layer made from an organic insulating material may be 0.5 μm˜2.5 μm.

When the thickness of the first passivation layer 407 is in the range of 0.5 μm˜2.5 μm, it can be assured that manufacture of the first passivation layer is completed in a shorter time, that is, the production efficiency is guaranteed, while an effect on the oxide semiconductor caused by hydrogen-containing groups is effectively avoided. If the thickness of the first passivation layer is too thin, it cannot function to avoid the oxide semiconductor from being affected by hydrogen-containing groups; and if the thickness of the first passivation layer is too thick, a longer tact time is needed, causing reduction of the production efficiency.

To ensure better characteristics of the device, in the present embodiment, an annealing process can be performed on the first passivation layer 407 (i.e., the first passivation layer 407 is a passivation layer subjected to an annealing process), so that the adverse effect on characteristics of the oxide semiconductor caused by hydrogen element and complex of hydrogen in the passivation layer can be reduced and thus the effect of enhancing stability of the device is achieved.

In the present embodiment, as for the first passivation layer 407, besides a silicon oxide thin film, a silicon nitride thin film, a silicon oxynitride thin film, an aluminum oxide thin film, a titanium oxide thin film, a zirconium oxide thin film, a tantalum oxide thin film, a barium titanate thin film or a neodymium oxide thin film, a thin film formed of another inorganic insulating material whose material characteristics are the same as or similar to each of the above substances may be used as well. Alternatively, besides a resin insulating film or an acrylic insulating film, a thin film formed of another organic insulating material whose material characteristics are the same as or similar to each of the above substances may be used as well.

In practice, because inorganic materials have a lower cost and a longer use lifetime, if requirements on flexible properties of the device are not taken into consideration, the passivation layer may be fabricated by using an inorganic material; because organic materials possess better flexible properties, if it is necessary for the processed device that factors in flexibility are emphasized, the passivation layer may be fabricated by using an organic material.

The structure of the gate insulating layer 403 in the present embodiment may be one-layered, two-layered or three-layered. When the gate insulating layer adopts a one-layered structure, it is called as a first gate insulating layer. The first gate insulating layer is a silicon oxide thin film, a silicon nitride thin film, a silicon oxynitride thin film, an aluminum oxide thin film or a titanium oxide thin film. A thickness of the first gate insulating layer may be 50 nm˜500 nm.

Certainly, in the present embodiment, as for the first gate insulating layer, besides a silicon oxide thin film, a silicon nitride thin film, a silicon oxynitride thin film, an aluminum oxide thin film or a titanium oxide thin film, a thin film formed of another inorganic insulating material whose material characteristics are the same as or similar to each of the above substances may be used as well.

To ensure better characteristics of the device, in the present embodiment an annealing process can be performed on the first gate insulating layer (i.e., the first gate insulating layer is an insulating layer subjected to an annealing process) so as to reduce the adverse effect on characteristics of the oxide semiconductor caused by hydrogen element and complex of hydrogen in the gate insulating layer.

When the gate insulating layer adopts a two-layered structure, it comprises a first gate insulating layer close to the gate electrode and a second gate insulating layer close to the active layer. The first gate insulating layer may be a silicon nitride thin film or a silicon oxynitride thin film, and the second gate insulating layer may be a silicon oxide thin film, an yttrium oxide thin film or a silicon oxynitride thin film. A thickness of the first gate insulating layer may be 50 nm˜600 nm, and a thickness of the second gate insulating layer may be 50 nm˜650 nm.

Certainly, in the present embodiment, as for the first gate insulating layer, besides a silicon nitride thin film or a silicon oxynitride thin film, a thin film formed of another inorganic insulating material whose material characteristics are the same as or similar to each of the above substances may be used as well. As for the second gate insulating layer, besides a silicon oxide thin film, a yttrium oxide thin film or a silicon oxynitride thin film, a thin film formed of another inorganic insulating material whose material characteristics are the same as or similar to each of the above substances may be used as well.

To ensure better characteristics of the device, in the present embodiment, an annealing process can be performed on the first gate insulating layer (i.e., the first gate insulating layer is an insulating layer subjected to an annealing process), so as to reduce the adverse effect on characteristics of the oxide semiconductor caused by hydrogen element and complex of hydrogen in the gate insulating layer. In the present embodiment, in order to achieve a better technical effect still further, an annealing process can be performed on the second gate insulating layer also.

Defects produced by the gate electrode can be suppressed by the material of the above first gate insulating layer favorably (especially when Cu or Cu alloy is adopted for the gate electrode). The function of the second gate insulating layer is to realize favorable match with the oxide semiconductor, and achieve the effect of enhancing properties of the device. The material for the second gate insulating layer typically is an oxide insulating layer in most cases, which material has a worse diffusion resistant ability with respect to groups such as H+, OH— and so on, and therefore, after the first gate insulating layer has been produced, an annealing process is preferably performed on the first gate insulating layer so as to reduce the groups such as H+, OH— and so on in the first gate insulating layer, which might be broken and diffused. Thus, the effect of enhancing stability of the device is achieved.

When the gate insulating layer adopts a three-layered structure, it comprises a first gate insulating layer close to the gate electrode, a second gate insulating layer, and a third gate insulating layer close to the active layer, and the second gate insulating layer is located between the first gate insulating layer and the third gate insulating layer. The first gate insulating layer may be a silicon nitride thin film, a silicon oxynitride thin film or the like inorganic insulating thin film; the second gate insulating layer may be a silicon oxynitride thin film or the like inorganic insulating thin film; and the third gate insulating layer may be a silicon oxide thin film, an aluminum oxide thin film, a titanium oxide thin film or the like inorganic insulating thin film.

A thickness of the first gate insulating layer may be 50 nm˜600 nm; a thickness of the second gate insulating layer may be 50 nm˜650 nm; and a thickness of the third gate insulating layer can be 20 nm˜600 nm.

In the present embodiment, the gate electrode may be made of Cu or Cu alloy, and may also be made of Mo, Mo—Al—Mo alloy, a stacked structure of Mo/Al—Nd/Mo, purified Al or Al alloy, Mo/Nd/Cu, Ti/Cu or the like metal. Of course, use of Cu or Cu alloy for the gate electrode has effects of optimizing the patterning process, enhancing properties of the device, reducing the cost, etc.

In the present embodiment, as for the first gate insulating layer, besides a silicon nitride thin film or a silicon oxynitride thin film, a thin film formed of another inorganic insulating material whose material characteristics are the same as or similar to each of the above substances may be used as well.

In the present embodiment, as for the second gate insulating layer, besides a silicon oxynitride thin film, a thin film formed of another inorganic insulating material whose material characteristics are the same as or similar to each of the above substance may be used as well.

In the embodiment, as for the third gate insulating layer, besides a silicon oxide thin film, an aluminum oxide thin film or a titanium oxide thin film, a thin film formed of another inorganic insulating material whose material characteristics are the same as or similar to each of the above substances may be used as well.

In the present embodiment, the first gate insulating layer adopts a silicon oxide thin film, a silicon oxynitride thin film or the like inorganic insulating material; defects produced in contact with the gate metal (especially when Cu and a Cu alloy is adopted as the gate electrode) can be suppressed well by the material although the direct contact with the oxide semiconductor will cause properties of the oxide semiconductor layer to degrade, thus the first gate insulating layer is disposed to be immediately close to the gate electrode but far away from the active layer. The second gate insulating layer is disposed as an intermediate layer. Because the second gate insulating layer made from a silicon oxynitride thin film or the like inorganic insulating material contains less content of the groups such as H+, OH— and so on per se, and further has a certain ability of penetration resistant with respect to the groups such as H+, OH— and so on, diffusion of the groups such as H+, OH— and so on toward the oxide semiconductor layer can be suppressed well. Thus, an object of enhancing stability of the device can be achieved. Moreover, in order to enhance characteristics of the device to a great extent, the third gate insulating layer is made to be immediately close to the oxide semiconductor, and good match with the oxide semiconductor can be obtained. Thus, an effect of enhancing stability of the device can be attained.

In the present embodiment, when the passivation layer adopts a single-layered structure, there is no limitation on the structure of the gate insulating layer, which can be a one-layered, two-layered or three-layered structure. The selection of a specific layer structure can be determined according to practical requirements.

A method for manufacturing the array substrate will be described below by taking as an example a single-layered passivation layer and a single-layered gate insulating layer. In connection with FIG. 3 and FIG. 4, the example of the method comprises the following steps.

Step S101, a gate metal thin film is formed on a substrate.

For example, a gate metal thin film is formed on a glass substrate 401. The gate metal thin film is usually produced by means of magnetron sputtering, copper or an alloy thereof may be selected as the material for the gate metal film, and its thickness can be 200 nm˜350 nm to keep sheet resistance at a relatively low level.

Step S102, the gate metal thin film is patterned.

By means of wet etching, the gate metal thin film is patterned so as to form a gate line and a gate electrode 402. Further, if necessary, a common electrode line may be produced simultaneously.

Step S103, a first gate insulating layer is formed on the gate electrode.

The gate insulating layer in the embodiment is in one layer, and silicon oxide thin film, silicon nitride, silicon oxynitride, aluminum oxide, titanium oxide or the like inorganic insulating material may be used to form the first gate insulating layer. A thickness of the first gate insulating layer may be 50 nm˜500 nm.

Step S104, an annealing process is performed on the first gate insulating layer.

For example, the annealing process can be optimized: the first gate insulating layer is dehydrogenized with a high-temperature annealing furnace, the annealing is carried out under the protection of nitrogen gas, vacuum, or rare gas, the annealing temperature may be 250° C.˜450° C., and the annealing time period may be 20 min˜150 min.

Or, the annealing process can also be optimized: a vacuum heating chamber is incorporated into a PECVD apparatus, the pressure therein may be 10⁻⁴ Pa˜1 Pa, and a dehydrogenizing process is performed on the first gate insulating layer; the temperature in the annealing chamber is 350° C.˜480° C., and the annealing time period may be 10 min˜30 min.

As the annealing process in the embodiment is an optimized annealing process, for the annealing process the process time period can be shortened, throughput of products can be increased and meanwhile and the investment on the equipment can be reduced, as compared to a conventional annealing process.

Step S105, an oxide semiconductor active layer is formed on the first gate insulating layer.

Indium gallium zinc oxide (IGZO), indium tin zinc oxide (ITZO), indium zinc oxide (IZO) and so on, as well as compositions of the above substances at different ratios, can be used for the oxide semiconductor.

Step S106, after the above active layer of an oxide semiconductor has been produced, an etch stop layer is formed thereon.

Step S107, a source-drain electrode layer for a thin film transistor (TFT) device is formed on the substrate after the above steps. The source electrode and the drain electrode in the source-drain electrode layer 406 contact the two sides of the active layer of an semiconductor layer 404, respectively, and are disposed opposite to each other.

Step S108, a first passivation layer is formed on the substrate after the above steps.

The first passivation layer 407 may be a silicon oxide thin film, a silicon nitride thin film, a silicon oxynitride thin film, an aluminum oxide thin film, a titanium oxide thin film, a zirconium oxide thin film, a tantalum oxide thin film, a barium titanate thin film, a neodymium oxide thin film or the like inorganic insulating material. A thickness of the first passivation layer may be 50 nm˜500 nm.

Or, the first passivation layer 407 may be a resin insulating film, an acrylic insulating film or the like organic insulating material. A thickness of the first passivation layer 407 may be 0.5 μm 2.5 μm.

Step S109, an annealing process is performed on the first passivation layer.

Because the oxide semiconductor active layer has been produced prior to step the step S109, for the sake of reducing an effect on the active layer caused by the annealing process to a great extent, the temperature adopted by the annealing process in step S109 cannot be too high.

A method of the annealing process may be as follows: a heating chamber, which is vacuumized or filled with air, is incorporated into a PECVD apparatus, and a dehydrogenizing process is performed on the first passivation layer; the temperature in the annealing chamber may be 200° C.˜350° C., and annealing time may be 15 min˜90 min.

Of course, in addition to the above given conditions for the annealing process, another existing annealing manner may also be selected according to practical circumstances if a dehydrogenizing process can be performed on the first passivation layer.

Step S110, a pixel electrode layer is formed on the substrate after the above steps.

In the present embodiment, in addition to the layered structure used for the gate insulating layer and/or the passivation layer, the manufacturing processes for other thin films can be implemented with conventional technical means, and they are not design points of this embodiment, and details thereof are omitted here.

Specific materials are selected for the gate insulating layer and the passivation layer in the present embodiment, it is possible that an adverse effect on the characteristics of the oxide semiconductor, which is caused by doped hydrogen element and complex of hydrogen in the gate insulating layer and the passivation layer as well as in the outside environment, is reduced. The gate metal in the present embodiment, in addition to Cu and an alloy thereof, may also commonly use Mo, Mo—Al—Mo alloy, a stacked structure of Mo/Al—Nd/Mo, purified Al or Al alloy, Mo/Nd/Cu, Ti/Cu or the like metal.

### Embodiment 2

The present embodiment differs from the embodiment 1 in that: the thin film transistor in an array substrate provided in the embodiment has a gate electrode over an active layer (i.e., an array structure of a top-gate type). A structure of a TN type is still described as an example in the present embodiment, and a passivation layer on the array substrate is located between the gate electrode and a pixel electrode layer. The structure and manufacturing method of the passivation layer are the same as the structure and manufacturing method of the passivation layer in the embodiment 1, and the details thereof are omitted here.

### Embodiment 3

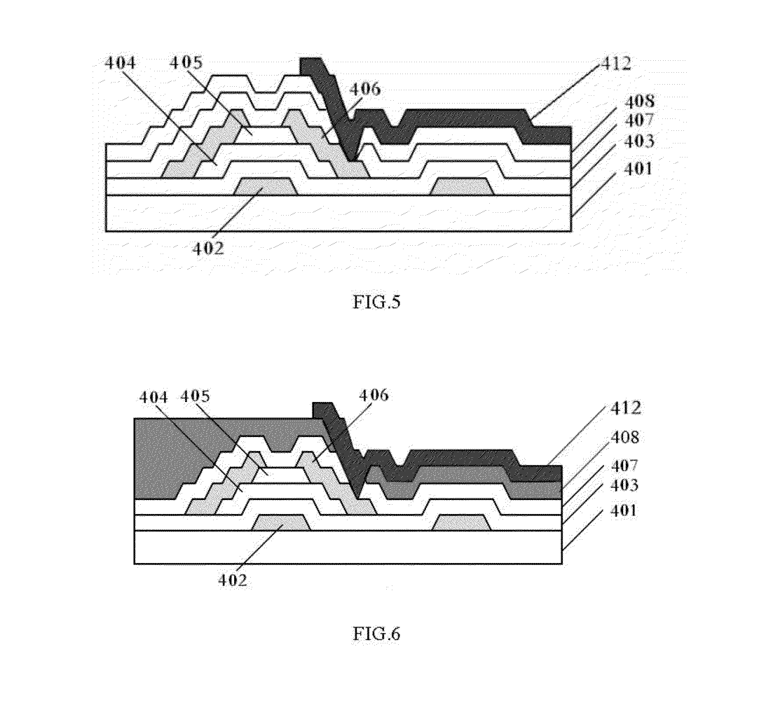

As shown in FIGS. 5 and 6, an array substrate provided in the present embodiment has such an array-substrate structure in which a gate electrode of a thin film transistor is at the bottom (i.e., a bottom-gate type).

The array substrate provided in the present embodiment comprises: a gate electrode 402 located on a substrate 401, a gate insulating layer 403 and an active layer 404 which are located over the gate electrode 402 respectively, a source-drain electrode layer 406, a pixel electrode layer 412 and a passivation layer. The gate insulating layer 403 is located between the gate electrode 402 and the active layer 404; and the passivation layer is located between the source-drain electrode layer 406 and the pixel electrode layer 412.

The active layer 404 is an oxide semiconductor, and the gate electrode and source and drain electrodes each may be Cu, Cu alloy, aluminum, aluminum alloy, chromium, molybdenum, titanium, neodymium, manganese, or an alloy or a stacked structure of the above metals. The passivation layer has a double-layered structure, comprising a first passivation layer 407 close to the source-drain electrode layer 406 and a second passivation layer 408 close to the pixel electrode layer 412. The first passivation layer 407 is a first inorganic insulating layer, which may comprise a silicon oxide thin film, an aluminum oxide thin film, an yttrium oxide thin film, a zirconium oxide thin film, a tantalum oxide thin film, a barium titanate thin film, a neodymium oxide thin film or a silicon oxynitride thin film. A thickness of the first passivation layer may be 50 nm˜600 nm.

The second passivation layer 408 is a second inorganic insulating layer or a first organic insulating layer; the second inorganic insulating layer may comprise a silicon nitride thin film, an yttrium oxide thin film, a silicon oxynitride thin film, a zirconium oxide thin film, a tantalum oxide thin film, a barium titanate thin film or a neodymium oxide thin film; and the first organic insulating layer may comprise a resin insulating film or an acrylic insulating film.

When the second passivation layer is an inorganic insulating layer, the thickness of the second passivation layer may be 50 nm˜500 nm; and when the second passivation layer is an organic insulating layer, the thickness of the second passivation layer may be 0.5 μm˜2.5 μm. Each of the first passivation layer and the second passivation layer is a passivation layer subjected to an annealing process, referring to FIG. 6.

With thicknesses of the above individual structural layers, it can be assured that manufacture of the first passivation layer is completed in a shorter time, that is, the production efficiency is guaranteed, while an adverse effect on the oxide semiconductor caused by hydrogen-containing groups is effectively avoided. If the thicknesses are set too thin, the effect of avoiding the oxide semiconductor from being affected by the hydrogen-containing group cannot be realized; and if the thicknesses are set too thick, a longer tact time is needed, causing reduction of the production efficiency.

In the present embodiment, as for the first passivation layer 407, besides the inorganic insulating material set forth above, a thin film formed of another inorganic insulating material whose material characteristics are the same as or similar to each of the above substances may be used as well.

In the present embodiment, as for the second passivation layer 408, besides a second inorganic insulating material set forth above, a thin film formed of another inorganic insulating material whose material characteristics are the same as or similar to each of the above substances may be used as well. Or, as for the second passivation layer, besides a first organic insulating material such as a resin insulating film, an acrylic insulating film or the like, a thin film formed of the like organic insulating material whose material characteristics are the same as or similar to each of the above substances may be used as well.

It should be noted that, an oxide is preferably selected as the material for the first passivation layer in the present embodiment, and an effective contact of this oxide with the oxide semiconductor layer at the position of the channel can be well established; a nitride is preferably selected for the second passivation layer, and this nitride can effectively prevent an interference on the oxide semiconductor layer which is exerted by hydrogen element or complex of hydrogen from outside.

Upon selection of a practical material, preferably different materials are selected for the first passivation layer and the second passivation layer respectively. When the first passivation layer and the second passivation layer adopt a same material, a structural design can be made on the material so that the passivation layer disposed close to the oxide semiconductor side is subjected to an oxygen-rich treatment to thereby increase oxygen content proportion in this substance, and the passivation layer disposed far away from the oxide semiconductor layer has a property of blocking permeation of external hydrogen atoms and water vapor to the thin film, thereby attaining required technical effects.

In the present embodiment, the first passivation layer 407 may adopt a first inorganic insulating material such as a silicon oxide thin film, an aluminum oxide thin film, a yttrium oxide thin film, a silicon oxynitride thin film or the like. These materials contain less content of the groups such as H+, OH— and so on per se and moreover have a certain ability of penetration resistant with respect to the groups such as H+, OH— and so on, so that diffusion of the groups such as H+, OH— and so on toward the oxide semiconductor layer can be suppressed well. Thus, an object of enhancing stability of the device is achieved and malfunction of the device is avoided. In order to enhance characteristics of the device to a great extent, it is possible that the second passivation layer which is made from a second inorganic insulating material such as silicon oxide, yttrium oxide, silicon oxynitride or the like or a first organic insulating material such as a resin insulating film, an acrylic insulating film or the like is immediately close to the pixel electrode layer. As such, an adhesion to the pixel electrode layer can be increased well, and an effect of enhancing stability of the device is attained.

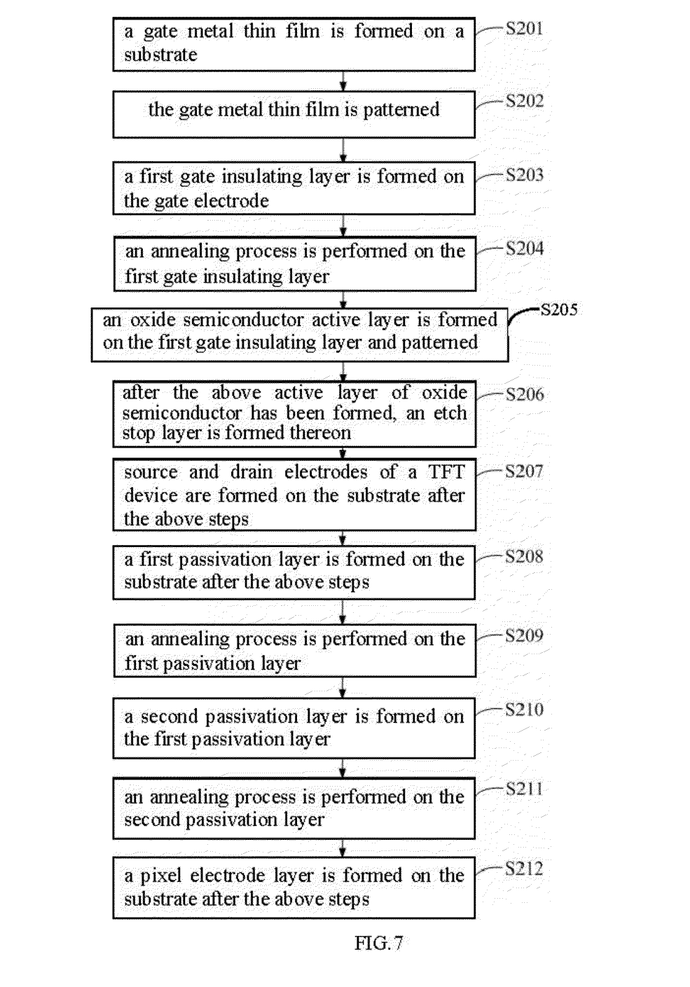

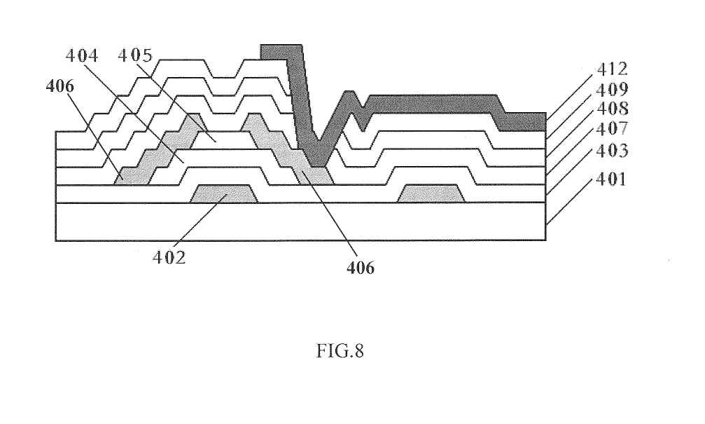

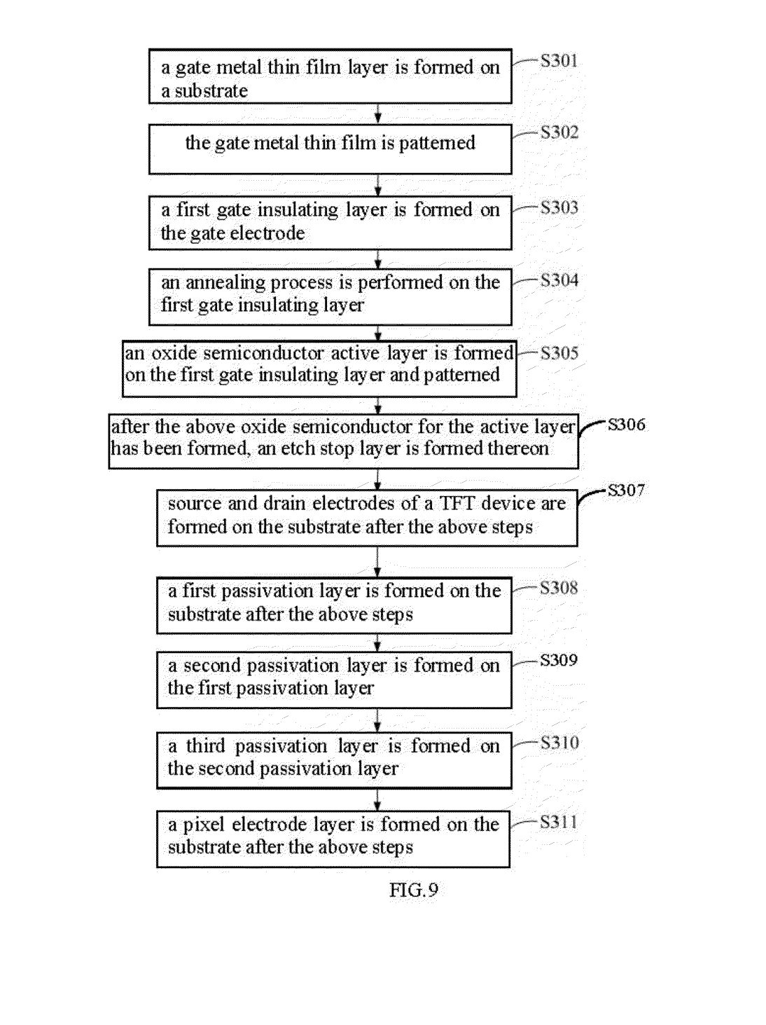

A method for manufacturing the array substrate will be described below in connection with an example in which a two-layered passivation layer and a single-layered gate insulating layer are adopted. As shown in FIG. 7, the example of the method comprises the following steps.

Step S201, a gate metal thin film is formed on a substrate.

For example, a gate metal thin film is formed on a glass substrate 401. The gate metal thin film is usually produced by means of magnetron sputtering, copper and an alloy thereof may be selected as the material for gate metal thin film, of which the thickness is usually 200 nm˜350 nm, and the sheet resistance is kept at a relatively low level.

Step S202, the gate metal thin film is patterned.

By means of wet etching, the gate metal thin film is patterned so as to form a gate line and a gate electrode 402. Further, if necessary, a common electrode line may be produced simultaneously.

Step S203, a first gate insulating layer is formed on the gate electrode.

For example, a silicon nitride thin film or a silicon oxynitride thin film is used to form the first gate insulating layer on the gate layer. A thickness of the first gate insulating layer may be 50 nm˜600 nm.

Step S204, an annealing process is performed on the first gate insulating layer.

An annealing process is performed after the first gate insulating layer is formed so as to decrease the content of the groups such as H+, OH— and so on in the first gate insulating layer which might be broken and diffused. Thus, an effect of enhancing stability of the device is achieved.

Step S205, an oxide semiconductor active layer is formed on the first gate insulating layer and patterned.

Generally, indium gallium zinc oxide (IGZO), indium tin zinc oxide (ITZO), indium zinc oxide (IZO) and so on, as well as compositions of the above substances in different ratios, may be used for the oxide semiconductor. The main manufacturing methods comprise a magnetron sputtering deposition method, a solution method, etc. There are two etching processes that are commonly used for the active-layer oxide semiconductor. i.e., one process is wet etching, and the other is dry etching. The widely used process at present is wet etching, and etch accuracy can be well controlled. The oxide semiconductor is patterned by means of etching. Each of the following embodiments is the same as the above, and therefore details thereof will no longer be repeated.

Step S206, after the above active layer of oxide semiconductor has been formed, an etch stop layer is formed thereon.

Step S207, source and drain electrodes of a TFT device are formed on the substrate after the above steps.

Step S208, a first passivation layer is formed on the substrate after the above steps.

The first passivation layer 407 is a first inorganic insulating layer, which may comprise a silicon oxide thin film, an aluminum oxide thin film, an yttrium oxide thin film, a zirconium oxide thin film, a tantalum oxide thin film, a barium titanate thin film, a neodymium oxide thin film or a silicon oxynitride thin film. A thickness of the first passivation layer may be 50 nm˜600 nm.

Step S209, an annealing process is performed on the first passivation layer.

The method of the annealing process may be: a heating chamber with nitrogen gas or air is incorporated into a PECVD apparatus, and a dehydrogenizing process is performed on the first passivation layer; the temperature in the annealing chamber may be 200′C.˜350° C., and the annealing time period may be 15 min˜90 min.

Step S210, a second passivation layer is formed on the first passivation layer.

The second passivation layer 408 is a second inorganic insulating layer or a first organic insulating layer, and the second inorganic insulating layer may comprise a silicon nitride thin film, an yttrium oxide thin film, a silicon oxynitride thin film, a zirconium oxide thin film, a tantalum oxide thin film, a barium titanate thin film or a neodymium oxide thin film. A thickness of the second passivation layer may be 50 nm˜500 nm. The first organic insulating layer may comprise a resin insulating film or an acrylic insulating film. A thickness of the second passivation layer made from an organic insulating thin film layer may be 0.5 μm˜2.5 μm.

Step S211, an annealing process is performed on the second passivation layer.

The method of the annealing process may be: a heating chamber with nitrogen gas or air is incorporated into a PECVD apparatus, and a dehydrogenizing process is performed on the second passivation layer; the temperature in the annealing chamber may be 200° C.˜350° C., and the annealing time period may be 15 min˜90 min.

Step S212, a pixel electrode layer is formed on the substrate after the above steps.

In the present embodiment, except for the layered structure used for the gate insulating layer and the passivation layer, steps of manufacturing process for other film structures can be implemented by conventional technical means; however, they are not the design points of this embodiment, and details thereof are omitted here. As for the gate insulating layer in this embodiment, in addition to that a single-layered structure can be adopted, a double-layered or three-layered structure as described in Embodiment 1 may also be used.

### Embodiment 4

The difference between the present embodiment and the embodiment 3 lies in that: an array substrate provided in the present embodiment is such an array substrate in which a gate layer for a thin film transistor is located on the top (i.e., an array substrate of a top-gate type). The passivation layer comprises a first passivation layer close to a gate electrode and a second passivation layer close to a pixel electrode layer. The structure, material and manufacturing method of the passivation layer are the same as the structure, material and manufacturing method of the passivation layer in the embodiment 3, and a process method for forming each structural layer is the same case as the embodiment 3, details thereof being omitted here.

### Embodiment 5

As shown in FIG. 8, an array substrate provided in the present embodiment has such an array-substrate structure in which a gate layer for a thin film transistor is at the bottom (i.e., a bottom-gate type). The array substrate provided in the present embodiment comprises: a gate electrode 402 located on a substrate 401, a gate insulating layer 403 and an active layer 404 which are located over the gate electrode 402 respectively, a source-drain electrode layer 406, a pixel electrode layer 412 and a passivation layer. The gate insulating layer 403 is located between the gate electrode 402 and the active layer 404; and the passivation layer is located between the source-drain electrode layer and the pixel electrode layer.

The active layer 404 is of an oxide semiconductor, the gate electrode is of Cu or Cu alloy, and the passivation layer has a three-layered structure comprising a first passivation layer 407 close to the source-drain electrode layer 406, a second passivation layer 408, and a third passivation layer 409 close to the pixel electrode layer 412. The second passivation layer 408 is located between the first passivation layer 407 and the third passivation layer 409.

The first passivation layer 407 is a first inorganic insulating layer, and the first inorganic insulating layer comprises a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film or the like inorganic insulating material. A thickness of the first passivation layer may be 50 nm˜600 nm.

The second passivation layer 408 is a second inorganic insulating layer or a first organic insulating layer; the second inorganic insulating layer may comprise a silicon oxide thin film, an aluminum oxynitride thin film, a zirconium oxynitride thin film, a tantalum oxynitride thin film, a neodymium oxynitride thin film or the like inorganic insulating material; and the first organic insulating layer may comprise a resin insulating thin film or an acrylic insulating thin film. The third passivation layer 409 is a third inorganic insulating layer or a second organic insulating layer; the third inorganic insulating layer may comprise a silicon nitride thin film, an aluminum nitride thin film, a zirconium nitride thin film, a tantalum nitride thin film or the like inorganic insulating material; and the second organic insulating layer may comprise a resin insulating thin film or an acrylic insulating thin film.

When the second passivation layer 408 is an inorganic insulating layer, a thickness of the second passivation layer may be 50 nm˜650 nm; and when the second passivation layer is an organic insulating layer, a thickness of the second passivation layer may be 0.5 μm˜2.5 μm. When the third passivation layer 409 is an inorganic insulating layer, a thickness of the third passivation layer 409 may be 50 nm˜500 nm; and when the third passivation layer 409 is an organic insulating layer, a thickness of the third passivation layer 408 may be 0.5 μm˜2.5 μm.

The inorganic insulating material of oxide which is adopted by the first passivation layer 407 close to the source-drain electrode layer 406 facilitates attachment to the oxide semiconductor active layer, thereby enhancing stability of the device. With the oxynitride or the like inorganic insulating material which is adopted by the second passivation layer 408, diffusion of the groups such as H+, OH— and so on toward the oxide semiconductor layer can be suppressed well thereby achieve an object of enhancing stability of the device and malfunction of the device is avoided, because the material contains less the groups such as H+, OH— and so on per se and further has a certain absorption ability with respect to the groups such as H+, OH— and so on. The material adopted by the third passivation layer 409 can prevent the device from being adversely affected by an outside hydrogen environment and further realize the effect of enhancing stability of the device.

With the thicknesses of the above individual structural layers, it can be assured that manufacture of the first passivation layer is completed in a shorter time, that is, the production efficiency is guaranteed, while an adverse effect on the oxide semiconductor caused by hydrogen-containing groups is effectively avoided. If the set thicknesses are too thin, an effect of avoiding the oxide semiconductor from being affected by the hydrogen-containing group cannot be realized; and if the set thicknesses are too thick, a longer tact time is needed, causing reduction of the production efficiency.

In the present embodiment, as for the first passivation layer, besides the material set forth above, a thin film formed of another inorganic insulating material whose material characteristics are the same as or similar to each of the above substances may be used as well.

In the present embodiment, as for the second passivation layer, besides the material set forth above, a thin film formed from other inorganic or organic insulating material whose material characteristics are the same as or similar to each of the above substances may be used as well.

In the present embodiment, as for the third passivation layer, besides the material set forth above, a thin film formed from other inorganic or organic insulating material whose material characteristics are the same as or similar to each of the above substances may be used as well.

The structure of the gate insulating layer in the present embodiment is the same as the structure of the gate insulating layer in the embodiment 1, and details thereof are omitted here.

A method for manufacturing the array substrate will be described below in connection with an example in which a three-layered passivation layer and a single-layered gate insulating layer are adopted. As shown in FIG. 9, the example of the method comprises the following steps.

Step S301, a gate metal thin film is formed on a substrate.

For example, a gate metal thin film is formed on a glass substrate 401. A gate metal thin film is usually produced by means of magnetron sputtering, and copper or an alloy thereof may be selected as the material for it, of which the thickness is usually 200 nm-350 nm, and the sheet resistance is kept at a relatively low level.

Step S302, the gate metal thin film is patterned.

For example, by means of wet etching, the gate metal thin film is patterned so as to farm a gate line and a gate electrode 402. Further, if necessary, a common electrode line may be produced simultaneously.

Step S303, a first gate insulating layer is formed on the gate electrode.

For example, a silicon nitride thin film or a silicon oxynitride thin film is used to form the first gate insulating layer on the gate layer. A thickness of the first gate insulating layer may be 50 nm˜600 nm.

Step S304, an annealing process is performed on the first gate insulating layer.

An annealing process is performed after the first gate insulating layer is formed, so as to decrease the content of the groups such as H+, OH— and so on in the first gate insulating layer which might be broken and diffused. Thus, an effect of enhancing stability of the device is achieved.

Step S305, an oxide semiconductor active layer is formed on the first gate insulating layer and patterned.

Generally, indium gallium zinc oxide (IGZO), indium tin zinc oxide (ITZO), indium zinc oxide (IZO) and so on, as well as compositions of the above substances in different ratios, may be used for the oxide semiconductor.

Step S306, after the above oxide semiconductor for the active layer has been formed, an etch stop layer is formed thereon.

Step S307, source and drain electrodes of a TFT device are formed on the substrate after the above steps.

Step S308, a first passivation layer is formed on the substrate after the above steps.

Step S309, a second passivation layer is formed on the first passivation layer.

Step S310, a third passivation layer is formed on the second passivation layer.

In the above steps, the first passivation layer 407 is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film or the like inorganic insulating material. A thickness of the first passivation layer may be 50 nm˜600 nm. The second passivation layer 408 may be a second inorganic insulating layer or a first organic insulating layer, the second inorganic insulating layer may comprise a silicon oxynitride thin film, an aluminum oxynitride thin film, a zirconium oxynitride thin film, a tantalum oxynitride thin film, a neodymium oxynitride thin film or the like inorganic insulating material, and the first organic insulating layer may comprise a resin insulating thin film or an acrylic insulating thin film. The third passivation layer 409 may be a third inorganic insulating layer or a second organic insulating layer. When the second passivation layer 408 is an inorganic insulating layer, a thickness of the second passivation layer may be 50 nm˜650 nm; and when the second passivation layer 408 is an organic insulating layer, a thickness of the second passivation layer may be 0.5 μm˜2.5 μm.

The third passivation layer 409 is a third inorganic insulating layer or a second organic insulating layer, the third inorganic insulating layer may comprise a silicon nitride thin film, an aluminum nitride thin film, a zirconium nitride thin film, a tantalum nitride thin film or the like inorganic insulating material, and the second organic insulating layer may comprise a resin insulating thin film or an acrylic insulating thin film.

When the third passivation layer 409 is an inorganic insulating layer, a thickness of the third passivation layer 409 may be 50 nm˜500 nm; and when the third passivation layer 409 is an organic insulating layer, a thickness of the third passivation layer 408 may be 0.5 μm˜2.5 μm.

Step S311, a pixel electrode layer is formed on the substrate after the above steps.

In the embodiment, except for the layered structure used for the gate insulating layer and the passivation layer, steps of manufacturing process for other film structures can be implemented by conventional technical means; they are not design points of this embodiment, and details thereof are omitted here. As for the gate insulating layer in the present embodiment, in addition to that the single-layered structure is adopted, a double-layered or three-layered structure as described in Embodiment 1 may also be used.

### Embodiment 6

The difference between the present embodiment and the embodiment 5 lies in that: an array substrate provided in the present embodiment is such an array substrate in which a gate layer for a thin film transistor is located on the top (i.e., an array substrate of a top-gate type). The passivation layer comprises a first passivation layer close to the gate layer, a second passivation layer, and a third passivation layer close to a pixel electrode layer. The second passivation layer is located between the first passivation layer and the third passivation layer. The structure, material and manufacturing method of the passivation layer are the same as the structure, material and manufacturing method of the passivation layer in the embodiment 5, and a specific processing method for forming each structural layer may be the same case as the embodiment 5, details thereof being omitted here.

### Embodiment 7

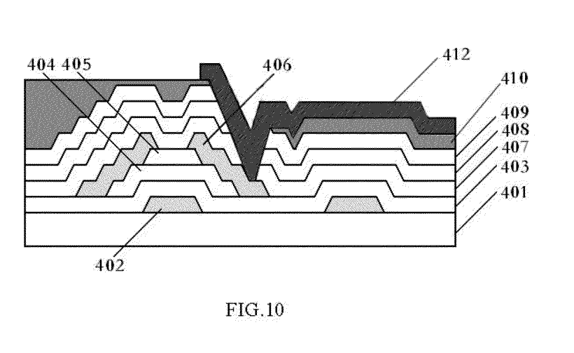

As shown in FIG. 10, an array substrate provided in the present embodiment has such an array-substrate structure in which a gate layer for a thin film transistor is at the bottom (i.e., a bottom-gate type). The array substrate provided in the present embodiment comprises: a gate electrode 402 located on a substrate 401, a gate insulating layer 403 and an active layer 404 which are located over the gate electrode 402 respectively, a source-drain electrode layer 406, a pixel electrode layer 412 and a passivation layer. The gate insulating layer 403 is located between the gate electrode 402 and the active layer 404; and the passivation layer is located between the source-drain electrode layer and the pixel electrode layer.

The active layer 404 is of an oxide semiconductor, the gate electrode is of Cu or a Cu alloy, and the passivation layer has a four-layered structure comprising a first passivation layer 407 close to the source-drain electrode layer 406, a second passivation layer 408, a third passivation layer 409, and a fourth passivation layer 410 close to the pixel electrode layer 412. The second passivation layer 408 and the third passivation layer 409 are located between the first passivation layer 407 and the fourth passivation layer 410.

The first passivation layer 407 is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, or a neodymium oxynitride thin film. The second passivation layer 408 is a second inorganic insulating layer, which may comprise an aluminum oxynitride thin film, a zirconium oxynitride thin film, a tantalum oxynitride thin film or a neodymium oxynitride thin film. The third passivation layer 409 is a third inorganic insulating layer, which may comprise a silicon nitride thin film, an aluminum nitride thin film, a zirconium nitride thin film or a tantalum nitride thin film. The fourth passivation layer 410 is a first organic insulating layer, which may comprise a resin insulating thin film or an acrylic insulating thin film.

A thickness of the first passivation layer 407 may be 50 nm˜600 nm; a thickness of the second passivation layer 408 may be 50 nm˜650 nm; a thickness of the third passivation layer 409 may be 50 nm˜500 nm; and a thickness of the fourth passivation layer may be 0.5 μm˜2.5 μm.

With thicknesses of the above individual structural layers, it is can assured that the manufacture of the first passivation layer is completed in a shorter time, that is, the production efficiency is guaranteed, while an effect on the oxide semiconductor caused by hydrogen-containing groups is effectively avoided. If the set thicknesses are too thin, an effect of avoiding the oxide semiconductor from being affected by the hydrogen-containing group cannot be realized; and if the set thicknesses are too thick, a longer tact time is needed, causing reduction of the production efficiency.

In the present embodiment, as for the first passivation layer, besides the material set forth above, a thin film formed of another inorganic insulating material whose material characteristics are the same as or similar to each of the above substances may be used as well.

In the present embodiment, as for the second passivation layer, besides the material set forth above, a thin film formed of another inorganic insulating material whose material characteristics are the same as or similar to each of the above substances may be used as well.

In the present embodiment, as for the third passivation layer, besides the material set forth above, a thin film formed of another inorganic insulating material whose material characteristics are the same as or similar to each of the above substances may be used as well.

In the present embodiment, as for the fourth passivation layer, besides the material set forth above, a thin film formed of the like organic insulating material whose material characteristics are the same as or similar to each of the above substances may be used as well.

In the present embodiment, with the silicon oxide thin film, the aluminum oxide thin film, the yttrium oxide thin film, the silicon oxynitride thin film or the like inorganic insulating material, which is employed by the first passivation layer, in cooperation with the silicon oxide thin film or the like inorganic insulating material employed by the second passivation layer, and the silicon nitride thin film or the like inorganic insulating material employed by the third passivation layer, diffusion of the groups such as H+, OH— and so on toward the oxide semiconductor layer can be suppressed well, an effect of enhancing stability of the device is achieved, and malfunction of the device is avoided, because these materials comprise less content of the groups such as H+, OH— and so on per se, and moreover have a certain ability of penetration resistant with respect to the groups such as H+, OH— and so on. In order to enhance characteristics of the device to a great extent, the fourth passivation layer is immediately close to the pixel electrode layer, by which adhesion to the pixel electrode layer can be increased as well. Thus, an effect of enhancing stability of the device is attained.

The structure of the gate insulating layer in the present embodiment is the same as the structure of the gate insulating layer in the embodiment 1, and details thereof are omitted here.

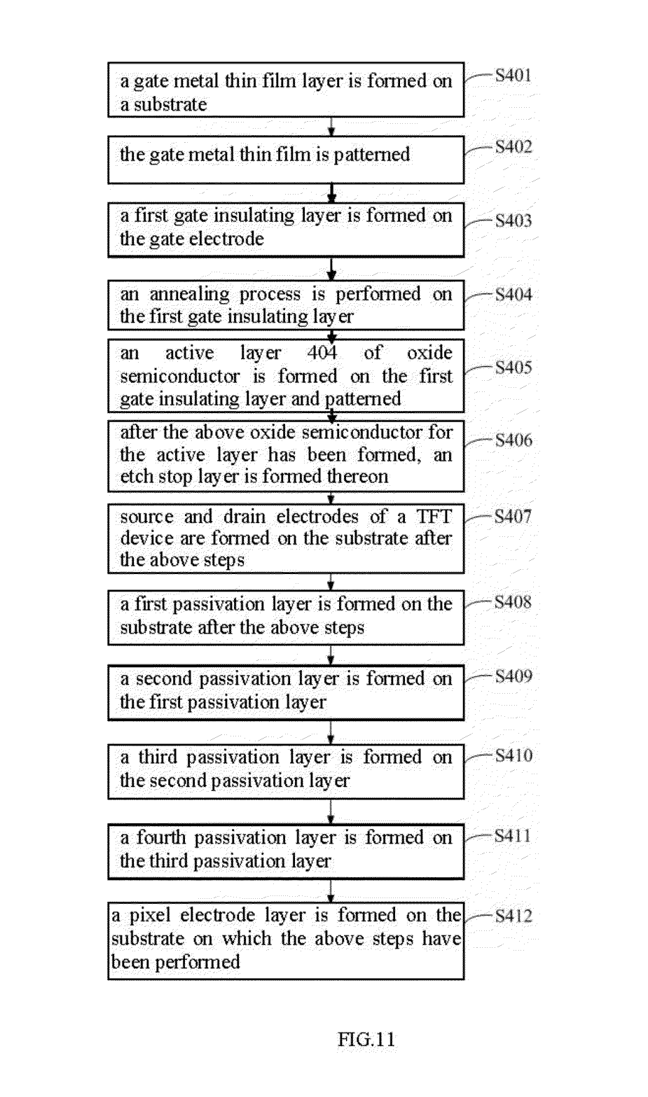

A method for manufacturing the array substrate will be described below in connection with an example in which a four-layered passivation layer and a single-layered gate insulating layer are adopted. As shown in FIG. 11, the example of the method comprises the following steps.

Step S401, a gate metal thin film is formed on a substrate.

For example, a gate metal thin film is formed on a glass substrate 401. A gate metal thin film is usually produced by means of magnetron sputtering, copper or an alloy thereof may be selected as the material for the gate metal thin film, of which the thickness is usually 200 nm˜350 nm, and the sheet resistance is kept at a relatively low level.

Step S402, the gate metal thin film is patterned.

For example, by means of wet etching, the gate metal thin film is patterned so as to form a gate line and a gate electrode 402. Further, if necessary, a common electrode line may be produced simultaneously.

Step S403, a first gate insulating layer is formed on the gate electrode.

For example, a silicon nitride thin film or a silicon oxynitride thin film is used to form the first gate insulating layer on the gate layer. A thickness of the first gate insulating layer may be 50 nm˜600 nm.

Step S404, an annealing process is performed on the first gate insulating layer.

An annealing process is performed after the first gate insulating layer is formed, so as to decrease the content of the groups such as H+, OH— and so on in the first gate insulating layer which might be broken and diffused. Thus, an effect of enhancing stability of the device is attained.

Step S405, an active layer 404 of oxide semiconductor is formed on the first gate insulating layer and patterned.

Generally, indium gallium zinc oxide (IGZO), indium tin zinc oxide (ITZO), indium zinc oxide (IZO) and so on, as well as compositions of the above substances in different ratios, may be used for the oxide semiconductor.

Step S406, after the above oxide semiconductor for the active layer has been formed, an etch stop layer is formed thereon.

Step S407, source and drain electrodes of a TFT device are formed on the substrate after the above steps.

Step S408, a first passivation layer is formed on the substrate after the above steps.

For example, the first passivation layer 407 is a first inorganic insulating layer, and the first inorganic insulating layer comprises a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a tantalum oxynitride thin film, or a neodymium oxynitride thin film. A thickness of the first passivation layer may be 50 nm˜600 nm.

Step S409, a second passivation layer is formed on the first passivation layer.

For example, the second passivation layer 408 is a second inorganic insulating layer, and the second inorganic insulating layer comprises an aluminum oxynitride thin film, a zirconium oxynitride thin film, a tantalum oxynitride thin film, or a neodymium oxynitride thin film. A thickness of the second passivation layer may be 50 nm˜650 nm.

Step S410, a third passivation layer is formed on the second passivation layer.

For example, the third passivation layer is a third inorganic insulating layer, and the third inorganic insulating layer comprises a silicon nitride thin film, an aluminum nitride thin film, a zirconium nitride thin film, or a tantalum nitride thin film. A thickness of the third passivation layer may be 50 nm˜500 nm.

Step S411, a fourth passivation layer is formed on the third passivation layer.

For example, the fourth passivation layer is a first organic insulating layer, and the first organic insulating layer comprises a resin insulating thin film or an acrylic insulating thin film. A thickness of the fourth passivation layer may be 0.5 μm˜2.5 μm.

Step S412, a pixel electrode layer is formed on the substrate on which the above steps have been performed.

In the present embodiment, except for the layered structure used for the gate insulating layer and the passivation layer, steps of manufacturing process for other film structures can be implemented by conventional technical means; they are not design points of this embodiment, and details thereof are omitted here. As for the gate insulating layer in the present embodiment, in addition to that the single-layered structure is adopted, a double-layered or three-layered structure as described in Embodiment 1 may also be used.

### Embodiment 8

The difference between the present embodiment and the embodiment 7 lies in that: an array substrate provided in the present embodiment is such an array substrate in which a gate layer for a thin film transistor is located on the top (i.e., an array substrate of a top-gate type). The passivation layer comprises a first passivation layer close to a gate electrode, a second passivation layer, a third passivation layer, and a fourth passivation layer close to a pixel electrode layer. The second passivation layer and the third passivation layer are located between the first passivation layer and the fourth passivation layer. The structure, material and manufacturing method of the passivation layer are the same as the structure, material and manufacturing method of the passivation layer in the embodiment 7, and a specific processing method for forming each structural layer may be the same case as the embodiment 7, details thereof being omitted here.

### Embodiment 9

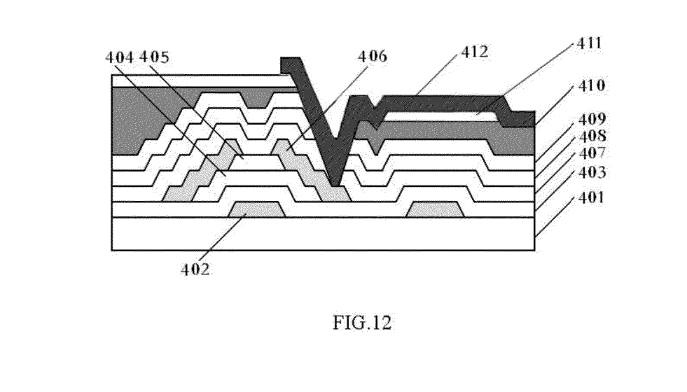

As shown in FIG. 12, an array substrate provided in the present embodiment has such an array-substrate structure in which a gate layer for a thin film transistor is at the bottom (i.e., a bottom-gate type). The array substrate provided in the present embodiment comprises: a gate electrode 402 located on a substrate 401, a gate insulating layer 403 and an active layer 404 which are located over the gate electrode respectively, a source-drain electrode layer 406, a pixel electrode layer 412 and a passivation layer. The gate insulating layer is located between the gate electrode and the active layer; and the passivation layer is located between the source-drain electrode layer and the pixel electrode layer.

The active layer 404 is of an oxide semiconductor, the gate electrode is of Cu or a Cu alloy, and the passivation layer has a five-layered structure comprising a first passivation layer 407, a second passivation layer 408, a third passivation layer 409, a fourth passivation layer 410, and a fifth passivation layer 411.

The first passivation layer 407 is close to the source-drain electrode layer 406, and the fifth passivation layer 411 is close to the pixel electrode layer 412; and the second passivation layer 408, the third passivation layer 409 and the fourth passivation layer 410 are located between the first passivation layer 407 and the fifth passivation layer 411.

The first passivation layer 407 is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, or a neodymium oxynitride thin film. The second passivation layer 408 is a second inorganic insulating layer, which may comprise an aluminum oxynitride thin film, a zirconium oxynitride thin film, a tantalum oxynitride thin film or a neodymium oxynitride thin film. The third passivation layer 409 is a third inorganic insulating layer, which may comprise a silicon nitride thin film, an aluminum nitride thin film, a zirconium nitride thin film or a tantalum nitride thin film. The fourth passivation layer 410 is a first organic insulating layer, which may comprise a resin insulating thin film or an acrylic insulating thin film. The fifth passivation layer 411 is a fourth inorganic insulating layer, which may comprise a silicon oxynitride thin film, a silicon oxide thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, a neodymium oxynitride thin film, a silicon nitride thin film, an aluminum nitride thin film, a zirconium nitride thin film or a tantalum nitride thin film. The fourth passivation layer employs an organic insulating material such as a resin insulating thin film, an acrylic insulating thin film or the like, so that aperture ratio of the array substrate can be effectively increased and coupling capacitance is decreased; and moreover, a planarization effect for reducing step difference can be realized. The fifth passivation layer employs an inorganic insulating material such as a silicon oxynitride thin film, a silicon oxide thin film, a silicon nitride thin film or the like, so that adhesion between the passivation layer and the pixel electrode layer can be strengthened and the problem that the organic insulating material fails during operation can be prevented effectively.

A thickness of the first passivation layer may be 50 nm˜600 nm; a thickness of the second passivation layer may be 50 nm˜650 nm; a thickness of the third passivation layer may be 50 nm˜500 nm; a thickness of the fourth passivation layer may be 0.5 μm˜2.5 μm; and a thickness of the fifth passivation layer can be 20 nm˜450 nm.

With thicknesses of the above individual structural layers, it can be assured that manufacture of the first passivation layer is completed in a shorter time, that is, the production efficiency is guaranteed, while an effect on the oxide semiconductor caused by hydrogen-containing groups is effectively avoided. If the set thicknesses are too thin, an effect of avoiding the oxide semiconductor from being affected by the hydrogen-containing group cannot be realized; and if the set thicknesses are too thick, a longer tact time is needed, causing reduction of the production efficiency.

In the present embodiment, as for the first passivation layer, besides the material set forth above, a thin film formed of another inorganic insulating material whose material characteristics are the same as or similar to each of the above substances may be used as well.

In the present embodiment, as for the second passivation layer, besides the material set forth above, a thin film formed of another inorganic insulating material whose material characteristics are the same as or similar to each of the above substances may be used as well.

In the present embodiment, as for the third passivation layer, besides the material set forth above, a thin film formed of another inorganic insulating material whose material characteristics are the same as or similar to each of the above substances may be used as well.

In the present embodiment, as for the fourth passivation layer, besides the material set forth above, a thin film formed of the like organic insulating material whose material characteristics are the same as or similar to each of the above substances may be used as well.

In the present embodiment, as for the fifth passivation layer, besides the material set forth above, a thin film formed of another inorganic insulating material whose material characteristics are the same as or similar to each of the above substances may be used as well.

The structure of the gate insulating layer in the embodiment is the same as structure of the gate insulating layer in the embodiment 1, and details thereof are omitted here.

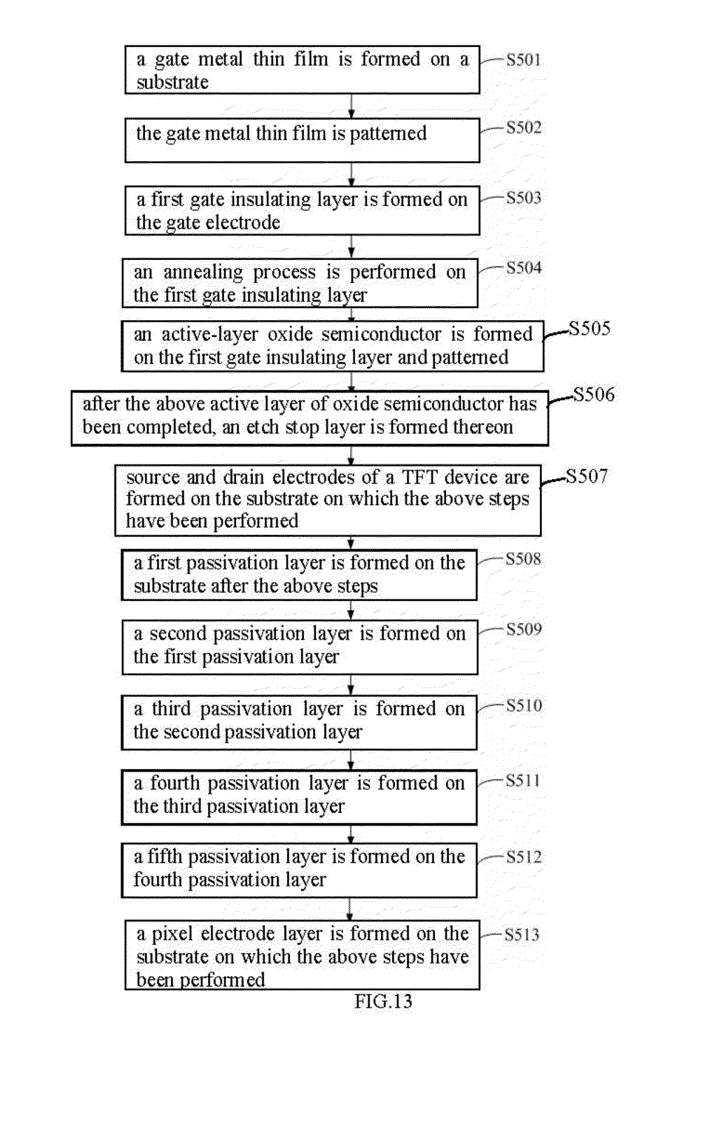

A method for manufacturing the array substrate will be described below in connection with an example in which a five-layered passivation layer and a single-layered gate insulating layer are adopted. As shown in FIG. 13, the example of the method comprises the following steps.

Step S501, a gate metal thin film is formed on a substrate.

For example, a gate metal thin film is formed on a glass substrate 401. A gate metal thin film is usually produced by means of magnetron sputtering, copper and an alloy thereof may be selected as the material for the electrode, of which the thickness is usually 200 nm˜350 nm, and the sheet resistance is kept at a relatively low level.

Step S502, the gate metal thin film is patterned.

For example, by means of wet etching, the gate layer is patterned so as to form a gate line and a gate electrode 402. Further, if necessary, a common electrode line may be produced simultaneously.

Step S503, a first gate insulating layer is formed on the gate electrode.

For example, a silicon nitride thin film or a silicon oxynitride thin film is used to form the first gate insulating layer on the gate layer. A thickness of the first gate insulating layer may be 50 nm˜600 nm.

Step S504, an annealing process is performed on the first gate insulating layer.

An annealing process is performed after the first gate insulating layer is formed, so as to decrease the content of the groups such as H+, OH— and so on in the first gate insulating layer which might be broken and diffused. Thus, an effect of enhancing stability of the device is attained.

Step S505, an active-layer oxide semiconductor is formed on the first gate insulating layer and patterned.

Generally, indium gallium zinc oxide (IGZO), indium tin zinc oxide (ITZO), indium zinc oxide (IZO) and so on, as well as compositions of the above substances in different ratios, may be adopted for the oxide semiconductor.

Step S506, after the above active layer of oxide semiconductor has been completed, an etch stop layer is formed thereon.

Step S507, source and drain electrodes of a TFT device are formed on the substrate on which the above steps have been performed.

Step S508, a first passivation layer is formed on the substrate after the above steps.

For example, the first passivation layer is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film or a neodymium oxynitride thin film. A thickness of the first passivation layer may be 50 nm˜600 nm.

Step S509, a second passivation layer is formed on the first passivation layer.

For example, the second passivation layer is a second inorganic insulating layer, and the second inorganic insulating layer comprises an aluminum oxynitride thin film, a zirconium oxynitride thin film, a tantalum oxynitride thin film, or a neodymium oxynitride thin film. A thickness of the second passivation layer may be 50 nm˜650 nm.

Step S510, a third passivation layer is formed on the second passivation layer.

For example, the third passivation layer is a third inorganic insulating layer, and the third inorganic insulating layer comprises a silicon nitride thin film, an aluminum nitride thin film, a zirconium nitride thin film, or a tantalum nitride thin film. A thickness of the third passivation layer may be 50 nm˜500 nm.

Step S511, a fourth passivation layer is formed on the third passivation layer.

The fourth passivation layer is a first organic insulating layer, which may comprise a resin insulating thin film or an acrylic insulating thin film. A thickness of the fourth passivation layer may be 0.5 μm˜2.5 μm.

Step S512, a fifth passivation layer is formed on the fourth passivation layer.

For example, the fifth passivation layer is a fourth inorganic insulating layer, and the fourth inorganic insulating layer comprises a silicon oxynitride thin film, a silicon oxide thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, a neodymium oxynitride thin film, a silicon nitride thin film, an aluminum nitride thin film, a zirconium nitride thin film or a tantalum nitride thin film. A thickness of the fifth passivation layer can be 20 nm˜450 nm.

Step S513, a pixel electrode layer is formed on the substrate on which the above steps have been performed.

In the present embodiment, except for the layered structure used for the gate insulating layer and the passivation layer, steps of manufacturing process for every other film structure can be implemented by conventional technical means; they are not design points of this embodiment, and details thereof are omitted here. As for the gate insulating layer in the embodiment, in addition to that the single-layered structure is adopted, a double-layered or three-layered structure as described in embodiment 1 may also be used.

### Embodiment 10

The difference between the present embodiment and the embodiment 9 lies in that: an array substrate provided in the present embodiment is such an array substrate in which a gate layer for a thin film transistor is located on the top (i.e., an array substrate of a top-gate type). The passivation layer comprises a first passivation layer close to the gate layer, a second passivation layer, a third passivation layer, a fourth passivation layer, and a fifth passivation layer close to a pixel electrode layer. The second passivation layer, the third passivation layer and the fourth passivation layer are located between the first passivation layer and the fifth passivation layer. The structure, material and manufacturing method of the passivation layer are the same as the structure, material and manufacturing method of the passivation layer in the embodiment 7, and a specific processing method for forming each structural layer is the same case as the embodiment 9, details thereof being omitted here.

### Embodiment 11

A method for manufacturing an array substrate will be described below in connection with an example which is based on the five-layered passivation layer in the embodiment 9 in combination with a three-layered gate insulating layer. The example of the method comprises the following steps.

Step S601, a gate metal thin film is formed on a substrate.

For example, a gate metal thin film is formed on a glass substrate. During manufacture of TFTs, gate electrodes are generally produced by means of magnetron sputtering, and the materials for the electrodes can be selected according to different device structures and process requirements. Gate metals which are usually employed comprise Mo, Mo—Al—Mo alloy, a stacked structure of Mo/Al—Nd/Mo, purified Al and Al alloy, Cu and Cu alloy, Mo/Nd/Cu, Ti/Cu or the like metals, the thicknesses are usually 200 nm-350 nm, and the sheet resistances are kept at a relatively low level.

Step S602, the gate metal thin film is patterned.

For example, by means of wet etching, the gate layer is patterned so as to form a gate electrode and a common electrode line.

Step S603, a silicon nitride thin film or a silicon oxynitride thin film is used to form a first gate insulating layer on the gate electrode. A thickness of the first gate insulating layer may be 50 nm˜300 nm.

Step S604, a silicon oxynitride thin film is used to form a second gate insulating layer on the first gate insulating layer.

Step S605, silicon oxide, aluminum oxide or titanium oxide is used to form a third gate insulating layer on the second gate insulating layer.

Step S606, an oxide semiconductor active layer is formed on the third gate insulating layer and patterned.

For the formation of the oxide semiconductor active layer, the oxide semiconductor may be indium gallium zinc oxide (IGZO), indium tin zinc oxide (ITZO), indium zinc oxide (IZO) or the like, as well as compositions consisted of the above substances in different ratios.

Step S607, an etch stop layer is formed and patterned.

The etch stop layer (ESL) is directly formed on the patterned oxide semiconductor layer, and it is usual that an inorganic insulating material, such as SiOx, SiNx, SiOxNy, Al₂O₃, TiOx, Y₂O₃ or the like, may be used, so that the damages to the oxide semiconductor thin film during patterning of a data line can be reduced. Moreover, stability of the device can be effectively improved, thereby avoiding the device from being affected by an external environment. A patterning is carried out on the ESL, and a dry etching method is usually adopted.

Step S608, the data line is formed.

Subsequent to the manufacturing processes of S606 and S607, the data line is formed. Firstly, a metal layer is deposited so as to form an electrode layer for data-line and power-supply-line. The metal layer is generally fabricated by means of magnetron sputtering, and the material for the metal layer can be selected according to different device structures and process requirements. Electrode metals which are usually adopted comprise Mo, Mo—Al—Mo alloy, a stacked structure of Mo/Al—Nd/Mo, Cu and metal titanium and alloys thereof, ITO electrode, Ti/Al/Ti, Mo/ITO, etc., the thicknesses are usually 100 nm-350 nm, and the sheet resistances are kept at a relatively low level. After formation of the metal electrode layer, a patterning process is performed thereon. Generally, it is patterned by means of wet etching.

Step S609, on the substrate after completion of the above steps, a first passivation layer is formed. The first passivation layer is a first inorganic insulating layer, which may comprise a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film or a neodymium oxynitride thin film. A thickness of the first passivation layer may be 50 nm˜600 nm.

Step S610, a second passivation layer is formed on the first passivation layer. The second passivation layer is a second inorganic insulating layer, and the second inorganic insulating layer may comprise an aluminum oxynitride thin film, a zirconium oxynitride thin film, a tantalum oxynitride thin film, or a neodymium oxynitride thin film. A thickness of the second passivation layer may be 50 nm˜650 nm.

Step S611, a third passivation layer is formed on the second passivation layer. The third passivation layer is a third inorganic insulating layer, and the third inorganic insulating layer may comprise a silicon nitride thin film, an aluminum nitride thin film, a zirconium nitride thin film, or a tantalum nitride thin film. A thickness of the third passivation layer may be 50 nm˜500 nm.

Step S612, a fourth passivation layer is formed on the third passivation layer. The fourth passivation layer is a first organic insulating layer, which may comprise a resin insulating thin film or an acrylic insulating thin film. A thickness of the fourth passivation layer may be 0.5 μm˜2.5 μm.

Step S613, a fifth passivation layer is formed on the fourth passivation layer. The fifth passivation layer is a fourth inorganic insulating layer, which may comprise a silicon oxynitride thin film, a silicon oxide thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, a neodymium oxynitride thin film, a silicon nitride thin film, an aluminum nitride thin film, a zirconium nitride thin film or a tantalum nitride thin film. A thickness of the fifth passivation layer can be 20 nm˜450 nm.

Step S614, a via-hole is formed by etching and a pixel electrode is formed by deposition and patterning.

An etching process of the via hole is carried out after formation of the passivation layer so as to achieve conductive lines and connection to a pixel electrode. After completion of the foregoing process, deposition and patterning of the pixel electrode are carried out. As shown in the figure, after formation of the via hole, a pixel electrode layer is formed and then patterned by means of wet etching. Indium tin oxide (ITO) is typically used as the material for the pixel electrode layer at present.

As for the above method of manufacturing the array substrate, except for manufacturing methods of the gate insulating layer and the passivation layer, other structural layers can be produced by a conventional processing method.

The foregoing embodiments and corresponding accompanied drawings each have been illustrated with a TN mode as an example for explaining the array substrate structure provided by the invention. In the structure of a TN mode array substrate, the pixel electrode is usually located above a passivation layer. Two layers of transparent electrode are contained in the structure of an ADS mode array substrate, and are located on the upper and lower sides of a passivation layer, respectively (e.g., the transparent electrode located under the passivation layer may be produced on a substrate directly); and the layer of transparent electrode which is located above the passivation layer may be a pixel electrode or a common electrode.

In an Advanced Super Dimensional Switching (ADS or AD-SDS) technology, a multi-dimensional electric field is formed by an electric field produced at edges of slit electrodes within the same plane and an electric field produced between a layer of the slit electrodes and a layer of a plate-like electrode so as to allow liquid crystal molecules of all alignment within a liquid crystal cell, which are located directly above the electrodes and between the slit electrodes, to be rotated, thereby enhancing the work efficiency of liquid crystals and increasing the transmissive efficiency. The Advanced Super Dimensional Switching technology can improve the picture quality of TFT-LCD products, and can realize advantages of high resolution, high transmissivity, low power consumption, wide viewing angle, high aperture ratio, low chromatic aberration, push Mura-free, etc.

Regarding the various array substrates as well as manufacturing methods thereof according to embodiments of the invention, they may be array substrates for liquid crystal display, such as TN mode array substrates, ADS mode array substrates, IPS mode array substrates or VA mode array substrates, and may also be array substrates for OLED display.

Furthermore, according to an embodiment of the invention, there is further provided a display device, comprising the foregoing array substrate. The display device comprises but is not limited to a liquid crystal panel, an OLED panel, a liquid crystal display, a liquid crystal television, a liquid crystal display panel, a tablet computer or other electronic display apparatus.

According to the display device, the array substrate and method for manufacturing the same provided by embodiments of the invention, the gate insulating layer and the passivation layer in the array substrate are produced by using a layered structure in combination with an annealing process. A hydrogen-containing group in the passivation layer and in the outside environment can be decreased to a great extent by using the layered structure, so that the oxide semiconductor can be effectively avoided from being affected by the hydrogen-containing group. Thus, stability of the whole TFT device is enhanced to a great extent, and yield of final products is increased.

The descriptions made as above are merely exemplary embodiments of the present invention, and not used to limit the protection scope of the invention. The protection scope of the present invention is defined by attached claims.

1. An array substrate, comprising a substrate and a thin film transistor and a pixel electrode which are formed on the substrate, the thin film transistor comprising a gate electrode, a gate insulating layer, an active layer, and source and drain electrodes, and being overlaid with a multilayered passivation layer; wherein the active layer of the thin film transistor is of an oxide semiconductor; and the multilayered passivation layer comprises at least one layer of inorganic insulating thin film or organic insulating thin film.

2. The array substrate claimed as claim 1, wherein the multilayered passivation layer includes a first passivation layer, a second passivation layer, and a third passivation layer which are disposed in sequence; wherein the first passivation layer is close to the thin film transistor;
the first passivation layer is a first inorganic insulating layer, which comprises a silicon oxide thin film, an aluminum oxide thin film, a titanium oxide thin film, a silicon oxynitride thin film, a zirconium oxide thin film, a tantalum oxide thin film, a barium titanate thin film or a neodymium oxide thin film;
the second passivation layer is a second inorganic insulating layer or a first organic insulating layer; the second inorganic insulating layer comprises a silicon oxynitride thin film, an aluminum oxynitride thin film, a zirconium oxynitride thin film, a tantalum oxynitride thin film, or a neodymium oxynitride thin film; and the first organic insulating layer comprises a resin insulating thin film or an acrylic insulating thin film; and
the third passivation layer is a third inorganic insulating layer or a second organic insulating layer; the third inorganic insulating layer comprises a silicon nitride thin film, an aluminum nitride thin film, a zirconium nitride thin film, or a tantalum nitride thin film; and the second organic insulating layer comprises a resin insulating thin film or an acrylic insulating thin film.

3. The array substrate claimed as claim 2, wherein the multilayered passivation layer further includes a fourth passivation layer disposed on the third passivation layer;
the first passivation layer is the first inorganic insulating layer, which comprises a silicon oxide thin film, an aluminum oxide thin film, a titanium oxide thin film, a silicon oxynitride thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, or a neodymium oxynitride thin film;
the second passivation layer is the second inorganic insulating layer, which comprises an aluminum oxynitride thin film, a zirconium oxynitride thin film, a tantalum oxynitride thin film, or a neodymium oxynitride thin film;
the third passivation layer is the third inorganic insulating layer, which comprises a silicon nitride thin film, an aluminum nitride thin film, a zirconium nitride thin film, or a tantalum nitride thin film; and
the fourth passivation layer is a first organic insulating layer, which comprises a resin insulating thin film or an acrylic insulating thin film.

4. The array substrate claimed as claim 2, wherein a thickness of the first passivation layer is 50 nm˜600 nm;
when the second passivation layer is an inorganic insulating layer, a thickness of the second passivation layer is 50 nm˜650 nm; and when the second passivation layer is an organic insulating layer, a thickness of the second passivation layer is 0.5 μm˜2.5 μm;
when the third passivation layer is an inorganic insulating layer, a thickness of the third passivation layer is 50 nm˜500 nm; and when the third passivation layer is an organic insulating layer, a thickness of the third passivation layer is 0.5 μm˜2.5 μm.

5. The array substrate claimed as claim 3, wherein the multilayered passivation layer further includes a fifth passivation layer provided on the fourth passivation layer;
the fifth passivation layer is a fourth inorganic insulating layer, which comprises a silicon oxynitride thin film, a silicon oxide thin film, a zirconium oxide thin film, a tantalum oxide thin film, a barium titanate thin film, a neodymium oxide thin film, an aluminum oxynitride thin film, a zirconium oxynitride thin film, a tantalum oxynitride thin film, a neodymium oxynitride thin film, a silicon nitride thin film, an aluminum nitride thin film, a zirconium nitride thin film or a tantalum nitride thin film.

6. The array substrate claimed as claim 5, wherein a thickness of the first passivation layer is 50 nm˜600 nm; a thickness of the second passivation layer is 50 nm˜650 nm; a thickness of the third passivation layer is 50 nm˜500 nm; a thickness of the fourth passivation layer is 0.5 μm˜2.5 μm; and a thickness of the fifth passivation layer is 20 nm˜450 nm.

7. The array substrate claimed as claim 1, wherein the multilayered passivation layer includes a first passivation layer and a second passivation layer; wherein the first passivation layer is close to the thin film transistor;
the first passivation layer is a first inorganic insulating layer, which comprises a silicon oxide thin film, an aluminum oxide thin film, an yttrium oxide thin film, a zirconium oxide thin film, a tantalum oxide thin film, a barium titanate thin film, a neodymium oxide thin film or a silicon oxynitride thin film;
the second passivation layer is a second inorganic insulating layer or a first organic insulating layer; the second inorganic insulating layer comprises a silicon nitride thin film, an yttrium oxide thin film, a silicon oxynitride thin film, a zirconium oxide thin film, a tantalum oxide thin film, a barium titanate thin film or a neodymium oxide thin film; and the first organic insulating layer comprises a resin insulating thin film or an acrylic insulating thin film.

8. The array substrate claimed as claim 7, wherein a thickness of the first passivation layer is 50 nm˜600 nm;
when the second passivation layer is an inorganic insulating layer, a thickness of the second passivation layer is 50 nm˜500 nm; and when the second passivation layer is an organic insulating layer, a thickness of the second passivation layer is 0.5 μm˜2.4 μm.

9. The array substrate claimed as claim 7, wherein each of the first passivation layer and the second passivation layer is a passivation layer subjected to an annealing process.

10. The array substrate claimed as claim 1, wherein the gate insulating layer is located between the active layer and the gate electrode; and the gate insulating layer comprises at least one layer of inorganic insulating thin film.

11. The array substrate claimed as claim 10, wherein the gate insulating layer includes a first gate insulating layer close to the gate electrode and a second gate insulating layer close to the active layer;
the first gate insulating layer is an aluminum oxynitride thin film, a silicon oxynitride thin film, a zirconium oxynitride thin film, a tantalum oxynitride thin film, an yttrium oxynitride thin film, a neodymium oxynitride thin film, a silicon nitride thin film, an aluminum nitride thin film, a zirconium nitride thin film or a tantalum nitride thin film; and the second gate insulating layer is a silicon oxide thin film, an yttrium oxide thin film, an aluminum oxide thin film, a titanium oxide thin film, a zirconium oxide thin film, a tantalum oxide thin film, a barium titanate thin film, a neodymium oxide thin film, an aluminum oxynitride thin film, a silicon oxynitride thin film, a zirconium oxynitride thin film, a tantalum oxynitride thin film, an yttrium oxynitride thin film or a neodymium oxynitride thin film.

12. The array substrate claimed as claim 11, wherein the first gate insulating layer is an insulating layer subjected to an annealing process; and the second gate insulating layer is an insulating layer subjected to an annealing process.

13. The array substrate claimed as claim 11, wherein a thickness of the first gate insulating layer is 50 nm-600 nm; and a thickness of the second gate insulating layer is 50 nm-650 nm.

14. The array substrate claimed as claim 10, wherein the gate insulating layer includes a first gate insulating layer close to the gate electrode, a second gate insulating layer, and a third gate insulating layer close to the active layer, and the second gate insulating layer is located between the first gate insulating layer and the third gate insulating layer;
wherein the first gate insulating layer is an aluminum oxynitride thin film, a silicon oxynitride thin film, a zirconium oxynitride thin film, a tantalum oxynitride thin film, an yttrium oxynitride thin film, a neodymium oxynitride thin film, a silicon nitride thin film, an aluminum nitride thin film, a zirconium nitride thin film or a tantalum nitride thin film; the second gate insulating layer is an aluminum oxynitride thin film, a silicon oxynitride thin film, a zirconium oxynitride thin film, a tantalum oxynitride thin film, an yttrium oxynitride thin film, or a neodymium oxynitride thin film; and the third gate insulating layer is a silicon oxide thin film, an yttrium oxide thin film, an aluminum oxide thin film, a titanium oxide thin film, a zirconium oxide thin film, a tantalum oxide thin film, a barium titanate thin film, a neodymium oxide thin film, an aluminum oxynitride thin film, a silicon oxynitride thin film, a zirconium oxynitride thin film, a tantalum oxynitride thin film, an yttrium oxynitride thin film or a neodymium oxynitride thin film.

15. The array substrate claimed as claim 1, wherein the gate electrode and/or the source and drain electrodes are electrodes of copper or copper alloy.
